(19) United States
(12) Patent Application Publication
(10) Pub. No.: US 2025/0054758 A1
(43) Pub. Date: Feb. 13, 2025

(54) SEMICONDUCTOR PHOTORESIST COMPOSITION AND METHOD OF FORMING PATTERNS USING THE COMPOSITION

(71) Applicant: SAMSUNG SDI CO., LTD., Yongin-si (KR)

(72) Inventors: Dong Wan RYU, Suwon-si (KR); Eunmi KANG, Suwon-si (KR); Young Keun Kim, Suwon-si (KR); Seol Hee LIM, Suwon-si (KR); Soobin LIM, Suwon-si (KR); Sukil KANG, Suwon-si (KR)

(21) Appl. No.: 18/787,853

(22) Filed: Jul. 29, 2024

(30) Foreign Application Priority Data
Aug. 8, 2023 (KR) 10-2023-0103690

(51) Int. Cl. H01L 21/027; H01L 21/02; H01L 21/311; H01L 21/3205; H01L 21/3213

(52) U.S. Cl. CPC H01L 21/0275; H01L 21/31144; H01L 21/32139; H01L 21/02164; H01L 21/0217; H01L 21/31105; H01L 21/32055

(57) ABSTRACT

A semiconductor photoresist composition includes: an organic tin compound represented by Chemical Formula 1; and a solvent:

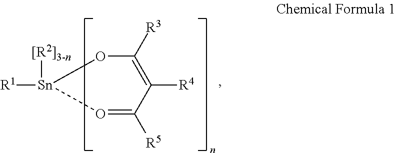

where the detailed description of Chemical Formula 1 is as described in the specification. In addition, a method of forming patterns includes: forming an etching-objective layer on a substrate; coating the semiconductor photoresist composition on the etching-objective layer to form a photoresist layer; patterning the photoresist layer to form a photoresist pattern; and etching the etching-objective layer with the photoresist pattern as an etching mask.

### CROSS-REFERENCE TO RELATED APPLICATION

This application claims priority to and the benefit of Korean Patent Application No. 10-2023-0103690, filed in the Korean Intellectual Property Office on Aug. 8, 2023, the entire content of which is incorporated herein by reference.

### BACKGROUND

### 1. Field

One or more aspects of embodiments of this disclosure are directed toward a semiconductor photoresist composition and a method of forming (or providing) patterns utilizing the same.

### 2. Description of the Related Art

EUV (extreme ultraviolet) lithography is considered to be important (or even essential) technology for manufacturing a next generation semiconductor device. The EUV lithography is a pattern-forming (or providing) technology utilizing an EUV ray having a wavelength of about 13.5 nm as a light exposure source. When EUV lithography is applied, an extremely fine pattern (e.g., less than or equal to about 20 nm) may be formed in an exposure process during a manufacture of a semiconductor device.

The extreme ultraviolet (EUV) lithography is realized through (e.g., is performed by) development of compatible photoresists, where the development (e.g., the process of developing a photoresist) can be performed at a spatial resolution of less than or equal to about 16 nm. Currently, efforts to overcome or mitigate insufficient or unsuitable specifications of chemically amplified (CA) photoresists such as resolution, photospeed, and/or feature roughness (also referred to as a line edge roughness or LER) for the next generation device are being pursued.

An intrinsic image blurring due to an acid catalyzed reaction in the polymer-type or kind photoresists may limit resolution in small feature sizes, a phenomenon that has been well known to occur in electron beam (e-beam) lithography. The chemically amplified (CA) photoresists are designed for relatively high sensitivity, but because their typical elemental makeups may reduce light absorbance of the photoresists at a wavelength of about 13.5 nm and thus decrease their sensitivity, the chemically amplified (CA) photoresists may partially have more difficulties under an EUV exposure.

In one or more embodiments, the CA photoresists may have difficulties in the small feature sizes due to roughness issues, and experiments tend to show line edge roughness (LER) of the CA photoresists is increased as photospeed is decreased, at least in part due to an essence (e.g., nature) of acid catalyst processes. Accordingly, a novel relatively high-performance photoresist is desired or required in a semiconductor industry because of these defects and problems of the CA photoresists.

In order to overcome the aforementioned drawbacks of the chemically amplified (CA) organic photosensitive composition, an inorganic photosensitive composition has been researched. The inorganic photosensitive composition is mainly utilized for negative tone patterning having resistance against removal by a developer composition due to chemical modification through nonchemical amplification mechanism. The inorganic composition contains an inorganic element having a higher EUV absorption rate than hydrocarbon and thus may secure sensitivity (e.g., sensitivity to EUV light) through the nonchemical amplification mechanism and in addition, may be less sensitive about a stochastic effect and thus may have relatively low line edge roughness and a relatively small number of defects.

Inorganic photoresists based on peroxopolyacids of tungsten mixed with tungsten, niobium, titanium, and/or tantalum have been reported as radiation sensitive materials for patterning (See also, as examples, U.S. Pat. No. 5,061,599; H. Okamoto, T. Iwayanagi, K. Mochiji, H. Umezaki, T. Kudo, Applied Physics Letters, 49(5), 298-300, 1986; the entire content of each of the two examples is incorporated herein by reference).

These materials may be effective or suitable for patterning large pitches for bilayer configuration as far ultraviolet (deep UV), X-ray, and/or electron beam sources. More recently, if (e.g., when) cationic hafnium metal oxide sulfate (HfSOx) materials along with a peroxo complexing agent have been utilized to image a 15 nm half-pitch (HP) through projection EUV exposure, improved performance has been obtained (See also, as examples, US 2011-0045406; J. K. Stowers, A. Telecky, M. Kocsis, B. L. Clark, D. A. Keszler, A. Grenville, C. N. Anderson, P. P. Naulleau, Proc. SPIE, 7969, 796915, 2011; the entire content of each of the two examples is incorporated herein by reference). This system exhibits a relatively high performance for a non-CA photoresist and has a practicable photospeed close to the one required (or desired) for an EUV photoresist. However, the hafnium metal oxide sulfate material having the peroxo complexing agent has a few practical drawbacks. First, these materials are coated in a mixture of corrosive sulfuric acid/hydrogen peroxide and have insufficient or unsuitable shelf-life stability. Second, a structural change thereof for performance improvement as a composite mixture is not easily achieved. Third, development should be performed in a TMAH (tetramethylammonium hydroxide) solution at an extremely relatively high concentration of about 25 wt % and/or the like.

Recently, research has been pursued to explore molecules containing tin as they may have excellent or suitable absorption of extreme ultraviolet rays. Among organotin polymer compounds, alkyl ligands may be dissociated by light absorption and/or secondary electrons produced thereby, and may be crosslinked with adjacent chains through oxo bonds, thus enabling the negative tone patterning which may not be removed by an organic developer. Such organotin polymer may exhibit greatly improved sensitivity as well as maintain a suitable resolution and line edge roughness, but it is desirable to further improve patterning characteristics thereof for commercial availability.

### SUMMARY

One or more aspects of embodiments of the present disclosure are directed toward a semiconductor photoresist composition having excellent or suitable sensitivity, improved storage stability against moisture, and improved coating characteristics.

One or more aspects of embodiments of the present disclosure are directed toward a method of forming (or providing) patterns utilizing the semiconductor photoresist composition.

Additional aspects will be set forth in part in the description which follows and, in part, will be apparent from the description, or may be learned by practice of the presented embodiments of the disclosure.

A semiconductor photoresist composition according to one or more embodiments includes an organic tin compound represented by Chemical Formula 1 and a solvent.

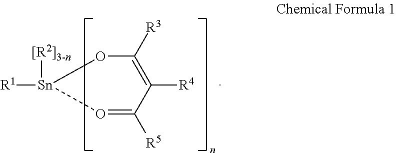

In Chemical Formula 1,

R¹ may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or L^{a}-O—R^{a} (wherein L^{a} may be a substituted or unsubstituted C1 to C20 alkylene group, and R^{a} may be a substituted or unsubstituted C1 to C20 alkyl group or a substituted or unsubstituted C6 to C30 aryl group),
R² may be a halogen, alkoxy and/or aryloxy (e.g., —OR^{b}, wherein R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), a carboxyl group (e.g., —O(CO)R⁶, wherein R⁶ may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), alkylamido and/or dialkylamido (e.g., —NR⁷R⁸, wherein R⁷ and R⁸ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), amidato (e.g., —NR⁹(COR¹⁰), wherein R⁹ and R¹⁰ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), or amidinato (e.g., —NR¹¹C(NR¹²)R¹³, wherein R¹¹, R¹², and R¹³ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof),
R³ to R⁵ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or L^{c}-O—R^{c}(wherein L^{c} may be a substituted or unsubstituted C1 to C20 alkylene group and R^{c} may be a substituted or unsubstituted C1 to C20 alkyl group or a substituted or unsubstituted C6 to C30 aryl group), and
n is one of integers of 1 to 3.

The method of forming (or providing) patterns according to one or more embodiments includes forming (or providing) an etching-objective layer on a substrate, coating the semiconductor photoresist composition on the etching-objective layer to form (or provide) a photoresist layer, patterning the photoresist layer to form (or provide) a photoresist pattern, and etching the etching-objective layer utilizing the photoresist pattern as an etching mask.

The semiconductor photoresist composition according to one or more embodiments can provide a photoresist pattern with improved storage stability against moisture, and improved coating characteristics and sensitivity.

### BRIEF DESCRIPTION OF THE DRAWINGS

These and/or other aspects will become apparent and more readily appreciated from the following description of the embodiments, taken in conjunction with the accompanying drawings in which:

FIGS. 1-5 are each a cross-sectional view for explaining a method of forming (or providing) patterns utilizing a semiconductor photoresist composition according to one or more embodiments.

### DETAILED DESCRIPTION

Hereinafter, referring to the drawings, embodiments of the present disclosure are described in more detail. In the following description of the present disclosure, functions or constructions that should be well understood by those of ordinary skill in the art will not be described for clarity of the present disclosure.

In order to clearly illustrate the present disclosure, some descriptions and relationships are not provided, and throughout the disclosure, the same or similar configuration elements are designated by the same reference numerals. Also, because the size and thickness of each configuration shown in the drawing are arbitrarily shown for better understanding and ease of description, the present disclosure is not necessarily limited thereto.

In the drawings, the thickness of layers, films, panels, regions, and/or the like, may be exaggerated for clarity. In the drawings, the thickness of a part of layers, regions, and/or the like, may be exaggerated for clarity. It will be understood that if (e.g., when) an element such as a layer, film, region, or substrate is referred to as being “on” another element, it can be directly on the other element (e.g., without any intervening elements therebetween) or intervening elements may also be present.

It will be understood that, although the terms first, second, etc. may be used herein to describe various elements, these elements should not be limited by these terms. These terms are only used to distinguish one element from another element. Thus, a first element could be termed a second element without departing from the teachings of the present invention. Similarly, a second element could be termed a first element.

As used herein, the singular forms “a,” “an,” and “the” are intended to include the plural forms as well, unless the context clearly indicates otherwise.

It will be further understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof.

As used herein, the terms “use,” “using,” and “used” may be considered synonymous with the terms “utilize,” “utilizing,” and “utilized,” respectively.

As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, the term “and/or” includes any and all combinations of one or more of the associated listed items.

Further, the use of “may” when describing embodiments of the present disclosure refers to “one or more embodiments of the present disclosure”.

Spatially relative terms, such as “beneath,” “below,” “lower,” “above,” “upper,” “bottom,” “top” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

As utilized herein, “substituted” refers to replacement of a hydrogen atom by deuterium, a halogen, a hydroxy group, a thiol group, a cyano group, a nitro group, —NRR′ (wherein, R and R′ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, a C1 to C20 sulfide group, and/or a (e.g., any suitable) combination thereof. “Unsubstituted” refers to non-replacement of a hydrogen atom by another substituent and remaining of the hydrogen atom.

As utilized herein, if (e.g., when) a definition is not otherwise provided, “an alkyl group” refers to a linear or branched aliphatic hydrocarbon group. The alkyl group may be “a saturated alkyl group” without any double bond or triple bond.

The alkyl group may be a C1 to C10 alkyl group. For example, the alkyl group may be a C1 to C8 alkyl group, a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, and/or a 2,2-dimethylpropyl group.

As utilized herein, if (e.g., when) a definition is not otherwise provided, “cycloalkyl group” refers to a monovalent cyclic aliphatic hydrocarbon group.

The cycloalkyl group may be a C3 to C10 cycloalkyl group, for example, a C3 to C8 cycloalkyl group, a C3 to C7 cycloalkyl group, or a C3 to C6 cycloalkyl group. For example, the cycloalkyl group may be a cyclopropyl group, a cyclobutyl group, a cyclopentyl group, and/or a cyclohexyl group, but the present disclosure is not limited thereto.

As utilized herein, “aryl group” refers to a substituent in which all atoms in the cyclic substituent have a p-orbital and these p-orbitals are conjugated and may include a monocyclic or fused ring polycyclic (i.e., rings sharing adjacent pairs of carbon atoms) functional group.

As utilized herein, unless otherwise defined, “alkenyl group” refers to an aliphatic unsaturated alkenyl group including at least one double bond in a linear or branched aliphatic hydrocarbon group.

As utilized herein, unless otherwise defined, “alkynyl group” refers to an aliphatic unsaturated alkynyl group including at least one triple bond in a linear or branched aliphatic hydrocarbon group.

In Chemical Formulae described herein, t-Bu refers to a tert-butyl group.

Hereinafter, a semiconductor photoresist composition according to one or more embodiments is described.

The semiconductor photoresist composition according to one or more embodiments includes organic tin compound represented by Chemical Formula 1 and a solvent.

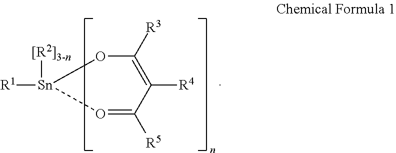

In Chemical Formula 1,
R¹ may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or L^{a}-O—R^{a} (wherein L^{a} is a substituted or unsubstituted C1 to C20 alkylene group, and R^{a} is a substituted or unsubstituted C1 to C20 alkyl group or a substituted or unsubstituted C6 to C30 aryl group),
R² may be a halogen, alkoxy and/or aryloxy (e.g., —OR^{b}, wherein R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), a carboxyl group (e.g., —O(CO)R⁶, wherein R⁶ may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), alkylamido and/or dialkylamido (e.g., —NR⁷R⁸, wherein R⁷ and R⁸ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), amidato (e.g., —NR⁹(COR¹⁰), wherein R⁹ and R¹⁰ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), or amidinato (e.g., —NR¹¹C(NR¹²)R¹³, wherein R¹¹, R¹², and R¹³ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof),
R³ to R⁵ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or L^{c}-O—R^{c}(wherein L^{c} may be a substituted or unsubstituted C1 to C20 alkylene group, and R^{c} may be a substituted or unsubstituted C1 to C20 alkyl group or a substituted or unsubstituted C6 to C30 aryl group), and
n is one of integers of 1 to 3.

The compound of the present disclosure includes a bidentate bond by an acetylacetonate ligand to tin, the central metal, so that two oxygen atoms are stably or suitably coordinated to the central metal, thereby improving sensitivity and storage stability against moisture.

For example, n may be integers from 1 or 2.

The organic tin compound according to the present disclosure may concurrently (e.g., simultaneously) include an ultraviolet group and a photosensitive reactive group in addition to an acetylacetonate ligand connected to tin, which is the central metal.

For example, R¹ may be a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or L^{a}-O—R^{a} (wherein L^{a} may be a substituted or unsubstituted C1 to C10 alkylene group, and R^{a} may be a substituted or unsubstituted C1 to C10 alkyl group).

For example, R¹ may be a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted tert-pentyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, a substituted or unsubstituted methoxy group, a substituted or unsubstituted ethoxy group, a substituted or unsubstituted propoxy group, and/or a (e.g., any suitable) combination thereof, and

R^{a} may be a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, and/or a (e.g., any suitable) combination thereof.

For example, R² may be a halogen, alkoxo and/or aryloxo (e.g., —OR^{b}, wherein R^{b} may be a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, and/or a (e.g., any suitable) combination thereof), a carboxyl group (e.g., —O(CO)R⁶, wherein R⁶ may be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, and/or a (e.g., any suitable) combination thereof), alkylamido and/or dialkylamido (e.g., —NR⁷R⁸, wherein R⁷ and R⁸ may each independently be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, and/or a (e.g., any suitable) combination thereof), amidato (e.g., —NR⁹(COR¹⁰), wherein R⁹ and R¹⁰ may each independently be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, and/or a (e.g., any suitable) combination thereof), or amidinato (e.g., —NR¹¹C(NR¹²)R¹³, wherein R¹¹, R¹², and R¹³ may each independently be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, and/or a (e.g., any suitable) combination thereof).

For example, R² may be a halogen, alkoxo and/or aryloxo (e.g., —OR^{b}, wherein R^{b} is a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, and/or a (e.g., any suitable) combination thereof), a carboxyl group (e.g., —O(CO)R⁶, wherein R⁶ may be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, and/or a (e.g., any suitable) combination thereof).

In one or more embodiments, R² may be a carboxyl group (—O(CO)R⁶, wherein R⁶ may be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, and/or a (e.g., any suitable) combination thereof).

For example, R^{b} may be a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, and/or a (e.g., any suitable) combination thereof, and

R⁶ may be hydrogen, a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, and/or a (e.g., any suitable) combination thereof.

For example, R³ to R⁵ may each independently be hydrogen, a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, and/or a (e.g., any suitable) combination thereof.

The organic tin compound may be represented by any one selected from among compounds listed in the Group 1.

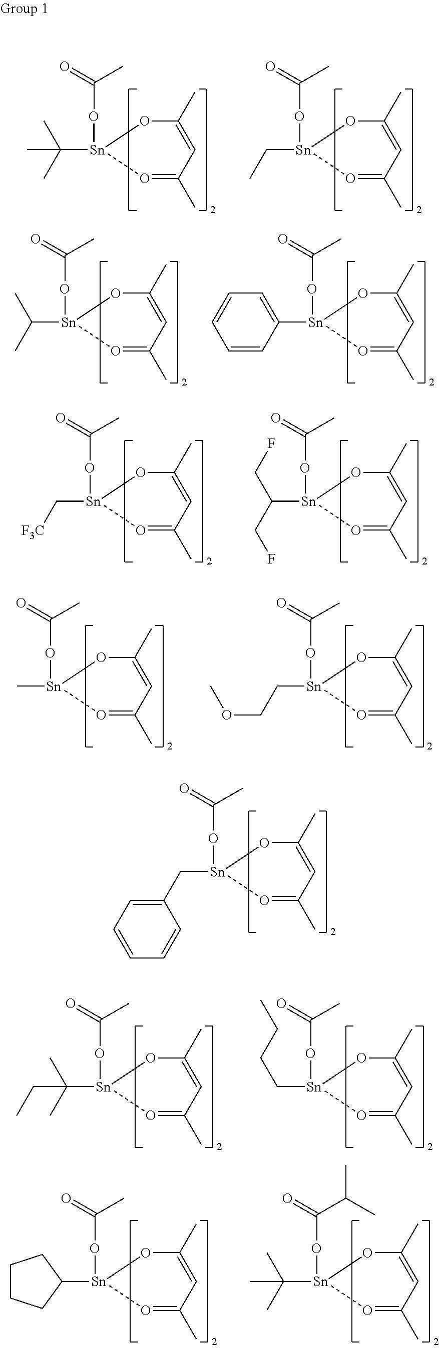

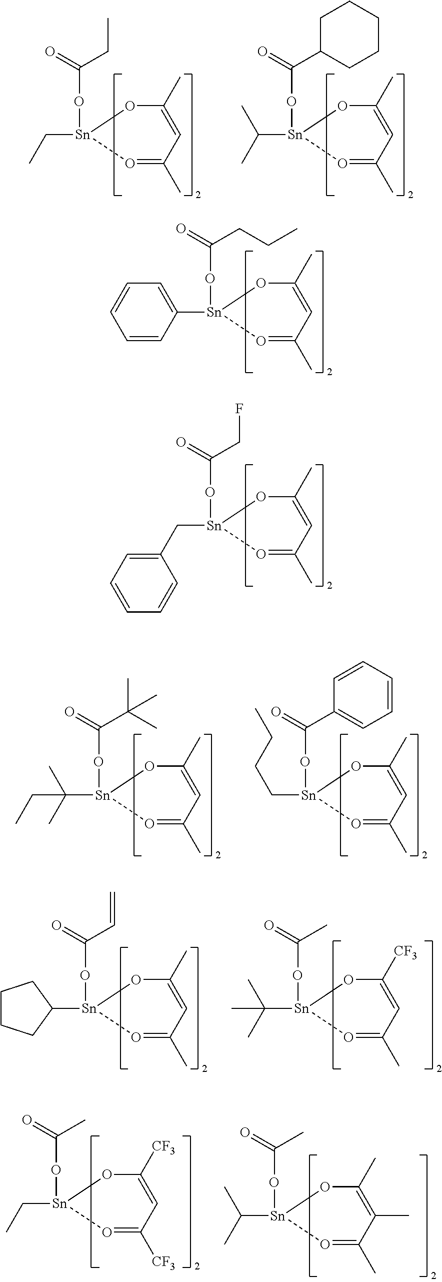

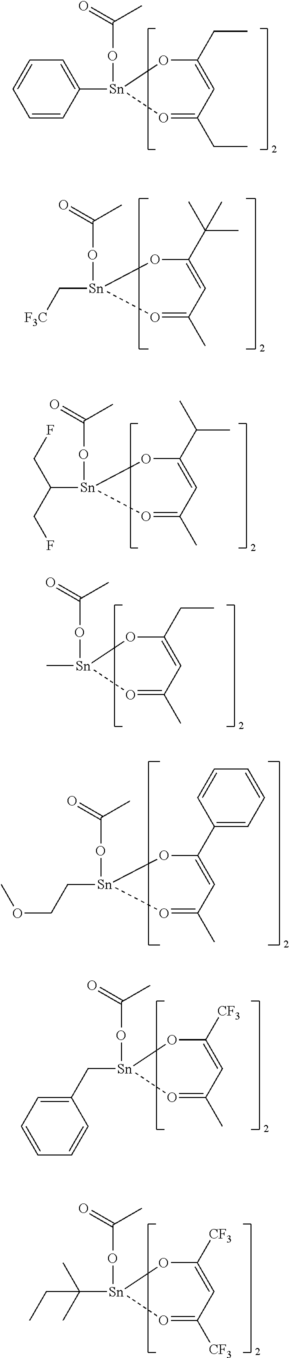

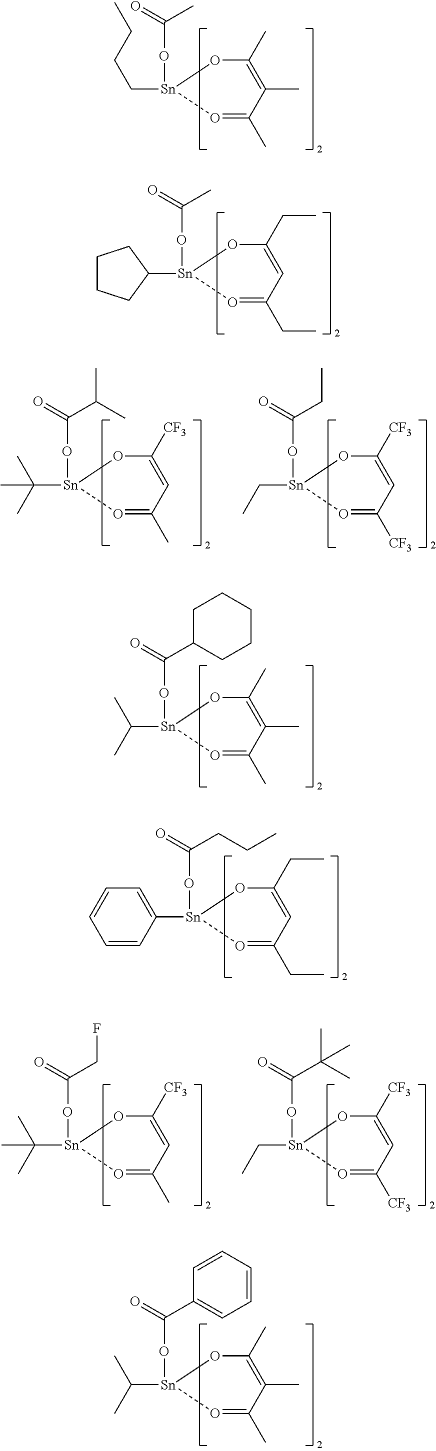

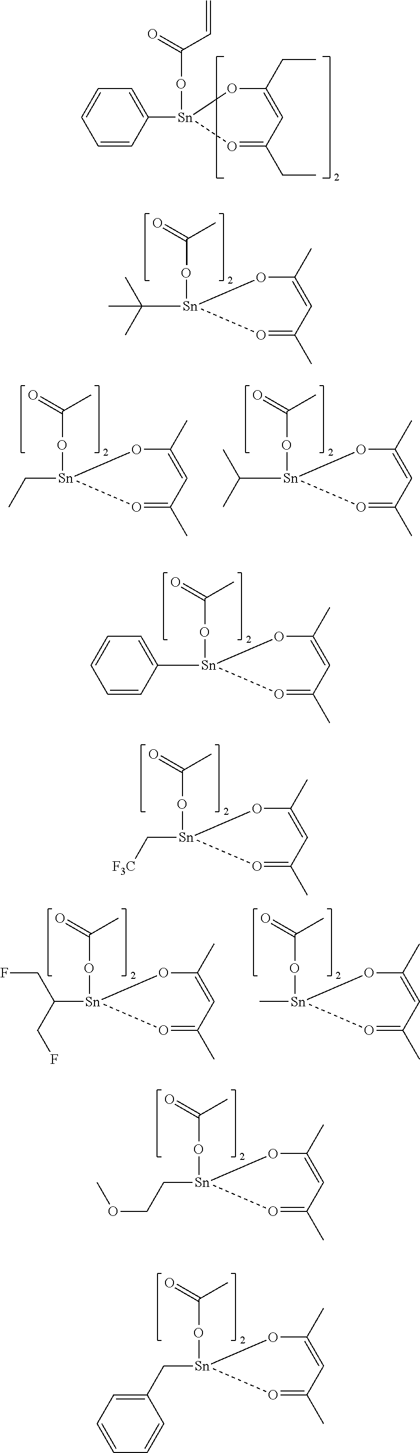

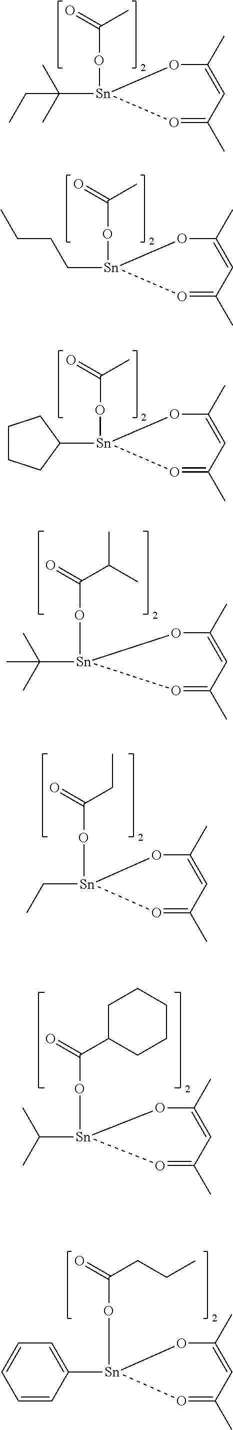

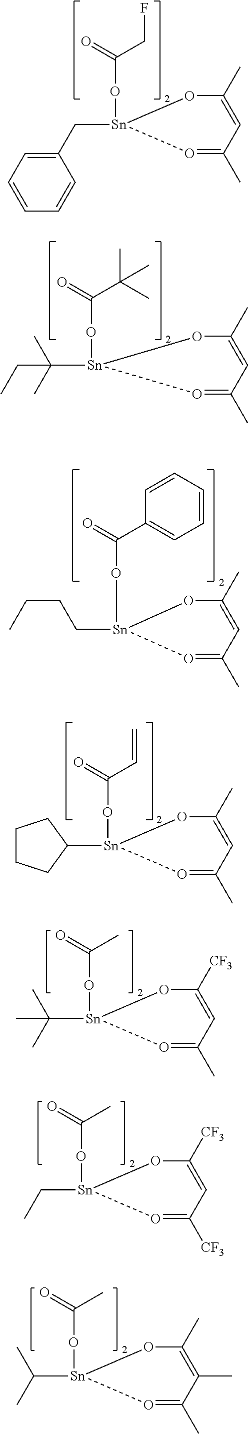

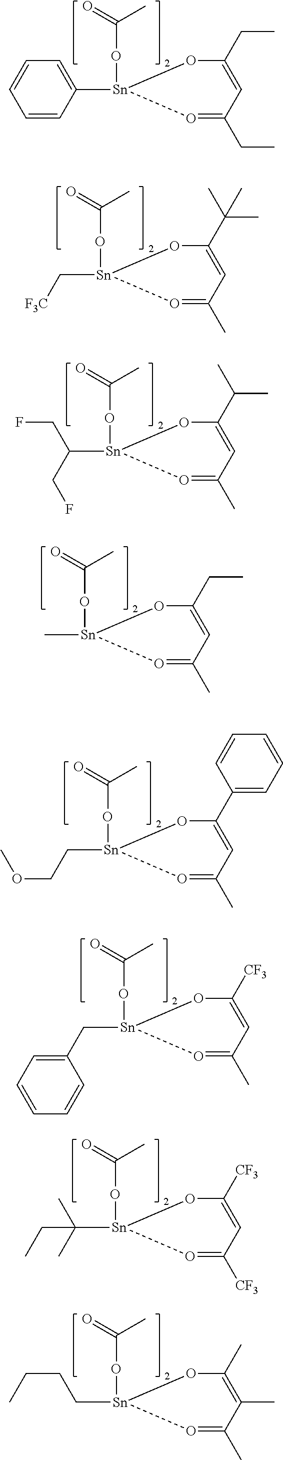

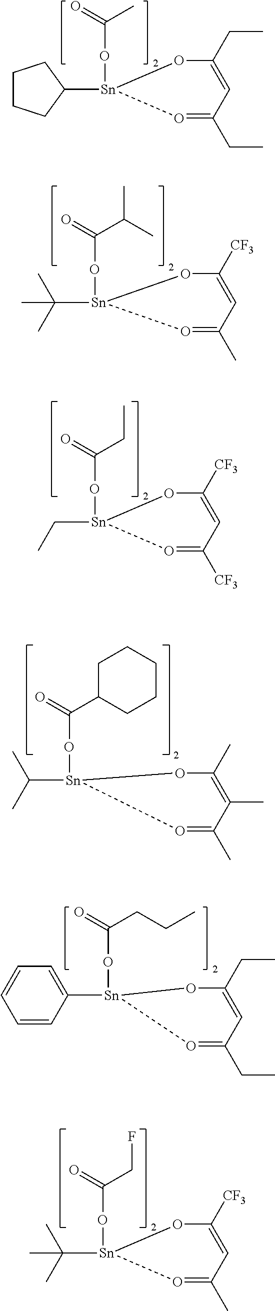

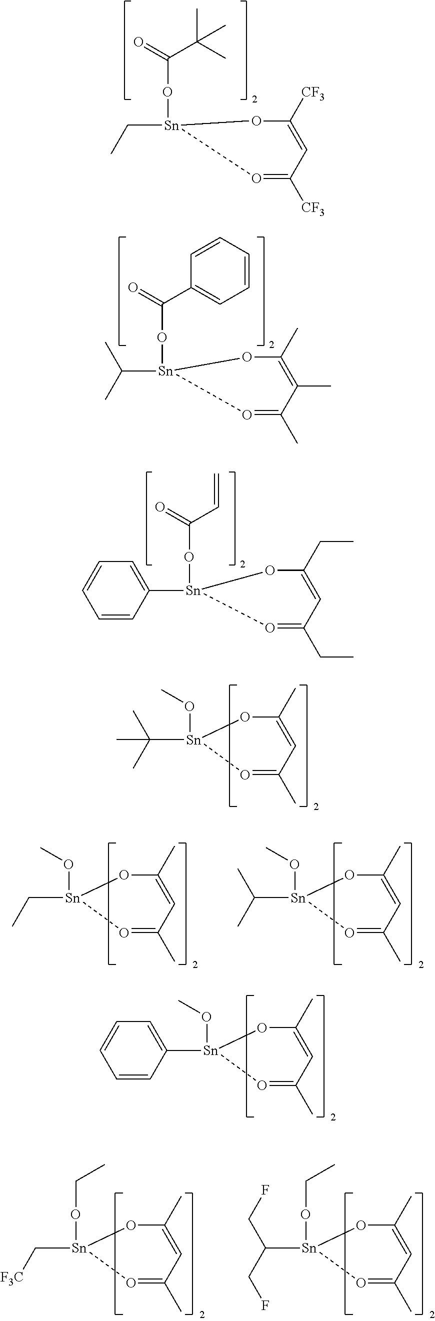

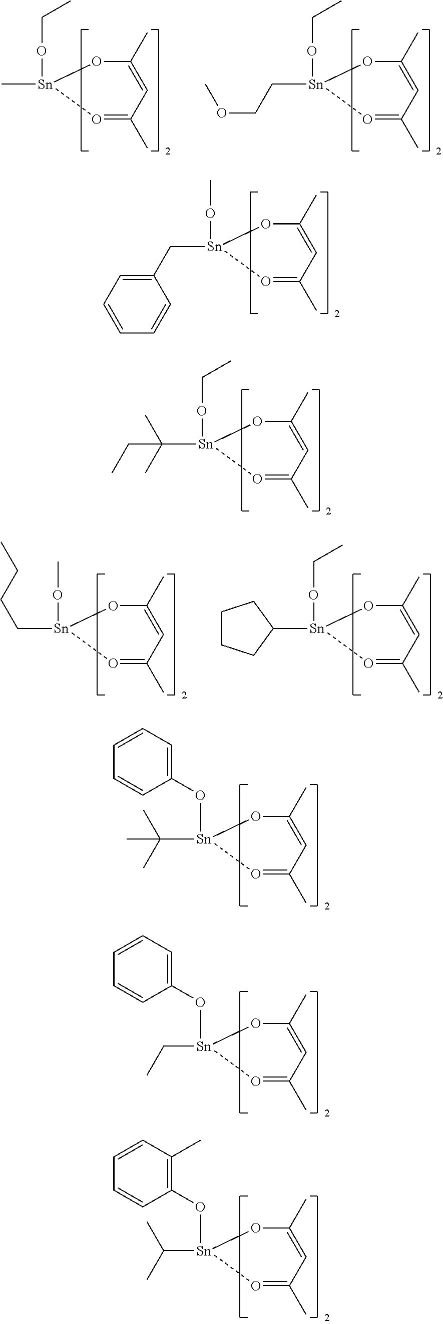

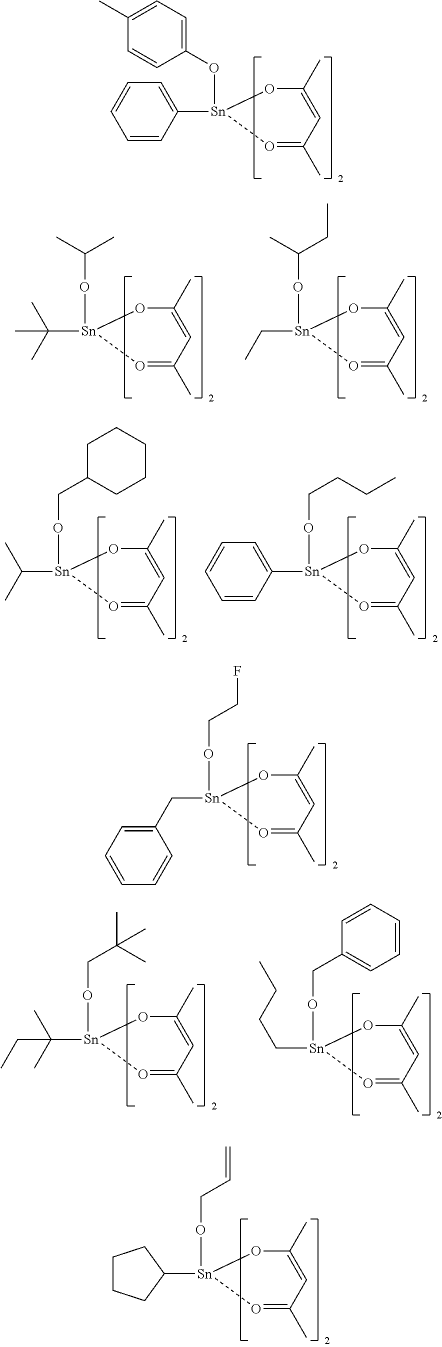

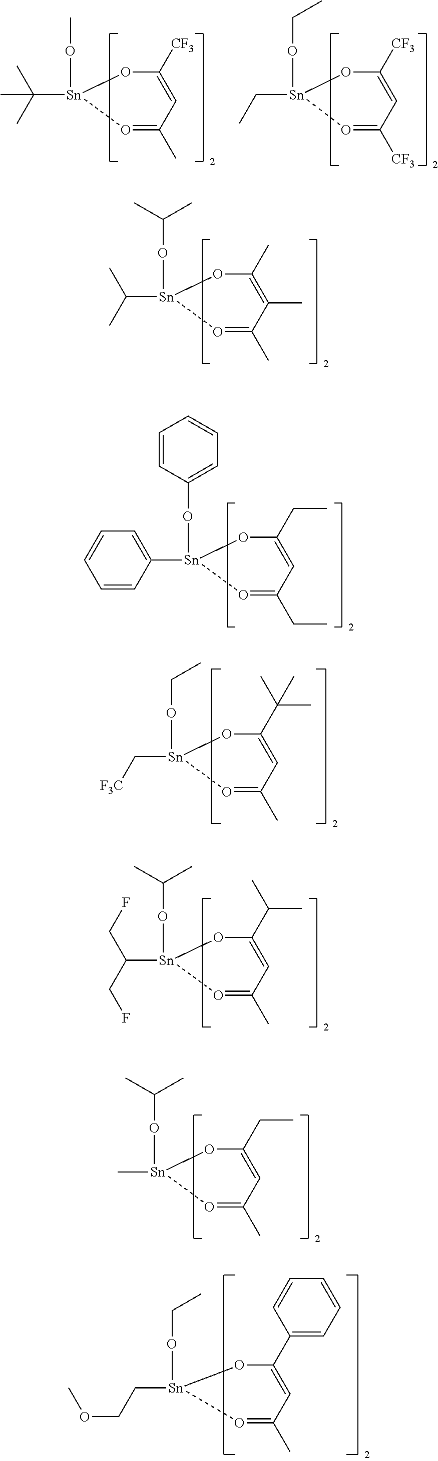

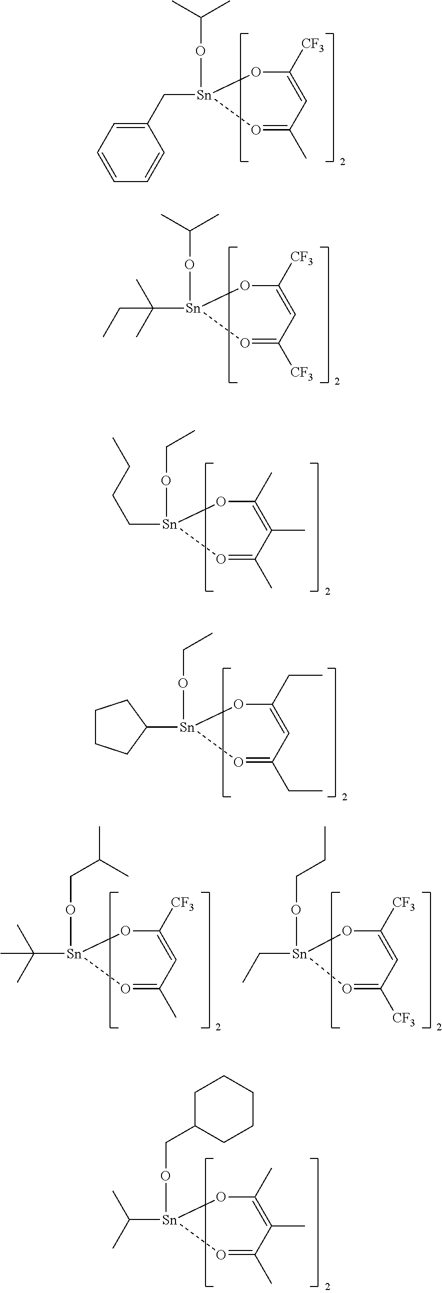

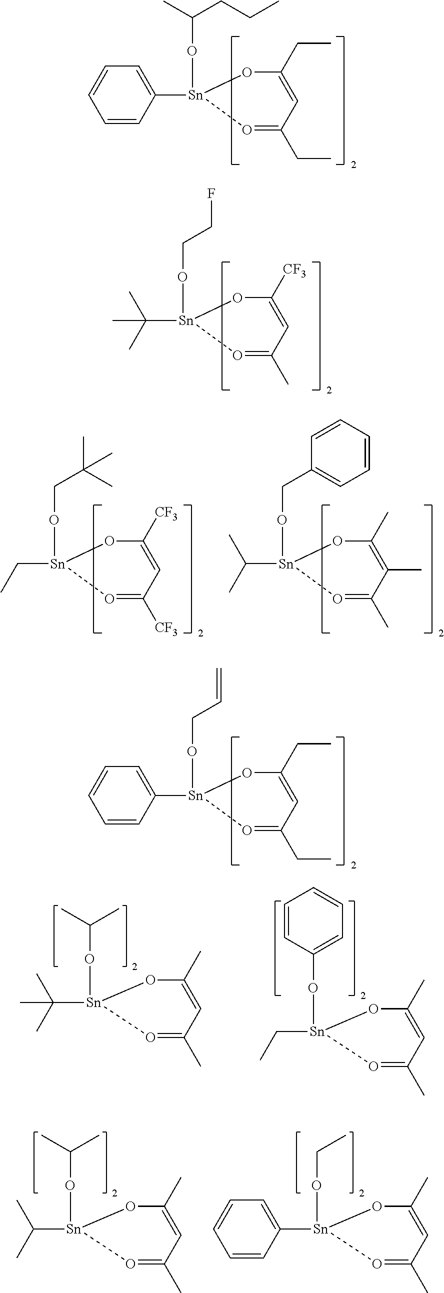

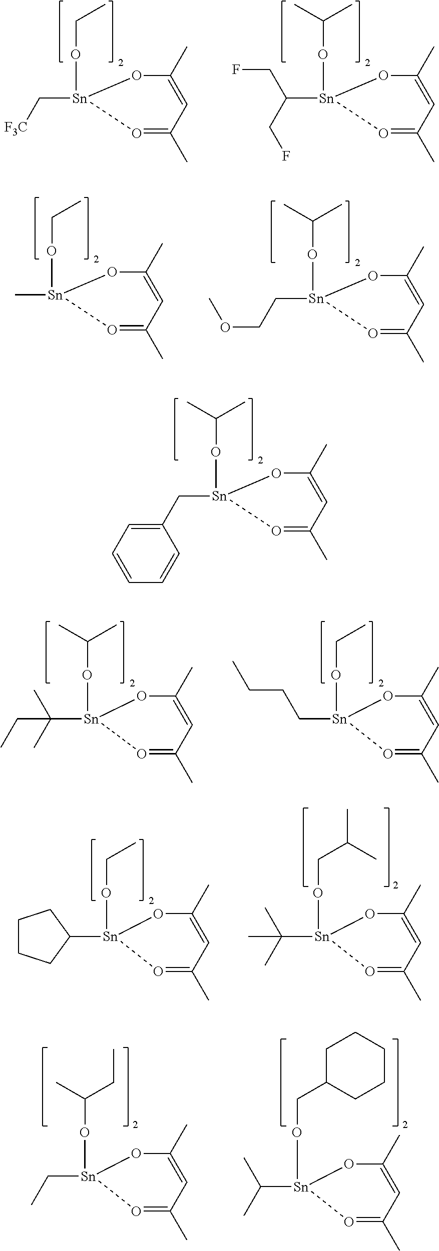

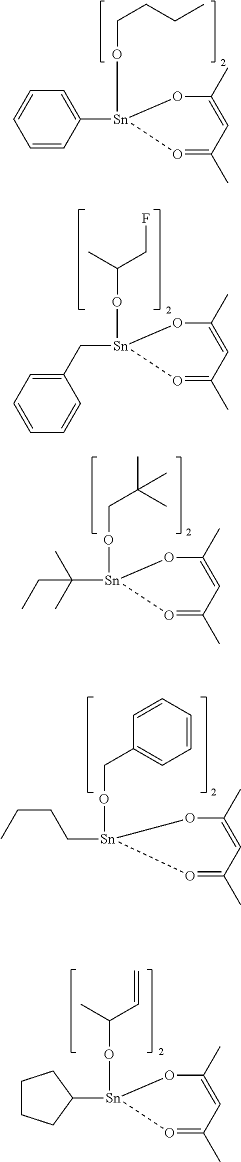

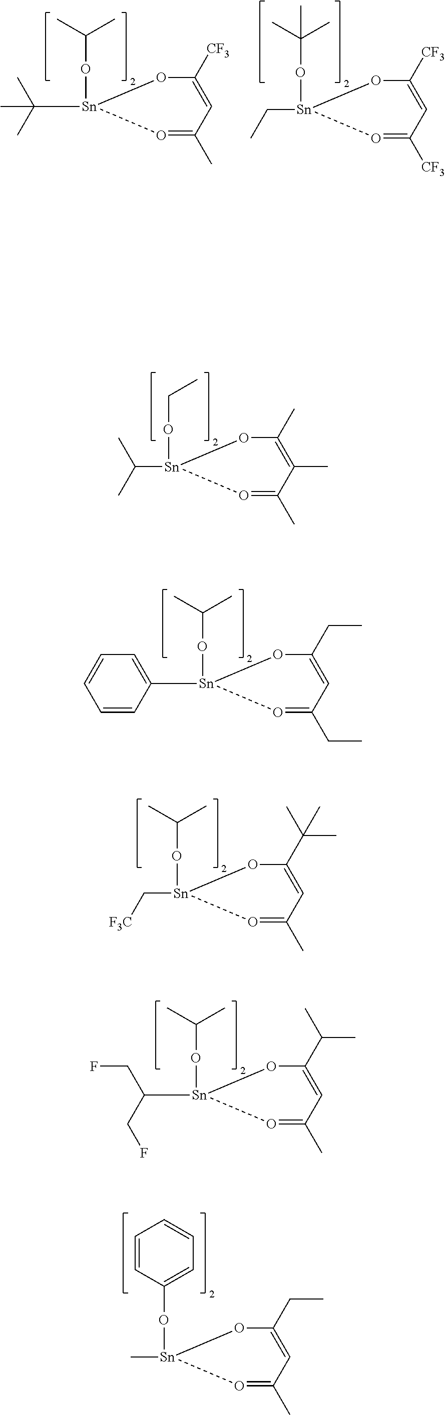

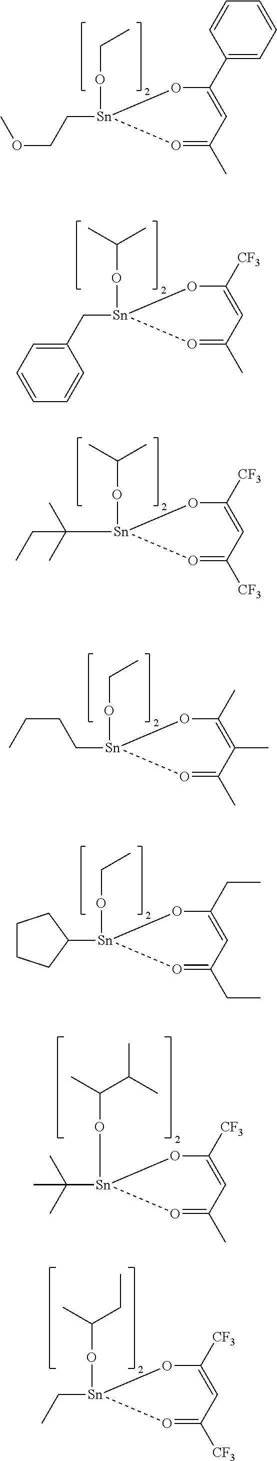

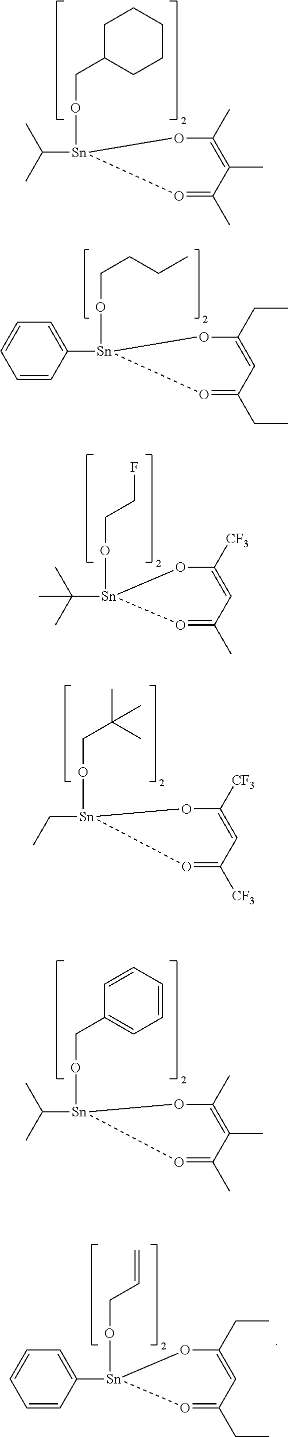

The organic tin compound strongly or suitably absorbs extreme ultraviolet light at about 3.5 nm and may have excellent or suitable sensitivity to high-energy light.

In the semiconductor photoresist composition according to one or more embodiments, based on 100 wt % of the semiconductor photoresist composition, the organic tin compound may be present in an amount of about 1 wt % to about 30 wt %, for example, about 1 wt % to about 25 wt %, for example about 1 wt % to about 20 wt %, for example about 1 wt % to about 15 wt %, for example about 1 wt % to about 10 wt %, or for example about 1 wt % to about 5 wt %, but the present disclosure is not limited thereto. If (e.g., when) the organic tin compound is included in the content (e.g., amount) within any of the above ranges, the storage stability and etch resistance of the semiconductor photoresist composition are improved, and the resolution characteristics are improved.

Because the photoresist composition according to one or more embodiments of the present disclosure includes the organic tin compound according to the present embodiments, it may be possible to provide the semiconductor photoresist composition having excellent or suitable sensitivity and stability.

The solvent of the semiconductor photoresist composition according to one or more embodiments may be an organic solvent, and may be, for example, selected from among aromatic compounds (e.g., xylene, toluene, and/or the like), alcohols (e.g., 4-methyl-2-pentenol, 4-methyl-2-propanol, 1-butanol, methanol, isopropyl alcohol, 1-propanol, and/or the like), ethers (e.g., anisole, tetrahydrofuran, and/or the like), esters (n-butyl acetate, propylene glycol monomethyl ether acetate, ethyl acetate, ethyl lactate, and/or the like), ketones (e.g., methyl ethyl ketone, 2-heptanone, and/or the like), and/or a (e.g., any suitable) mixture thereof, but the present disclosure is not limited thereto.

The semiconductor resist composition according to one or more embodiments may further include a resin in addition to the organometallic compound, vinyl group-containing acid compound, and solvent.

The resin may be a phenolic resin including at least one aromatic moiety of (e.g., at least one selected from among the aromatic moieties of) Group 2.

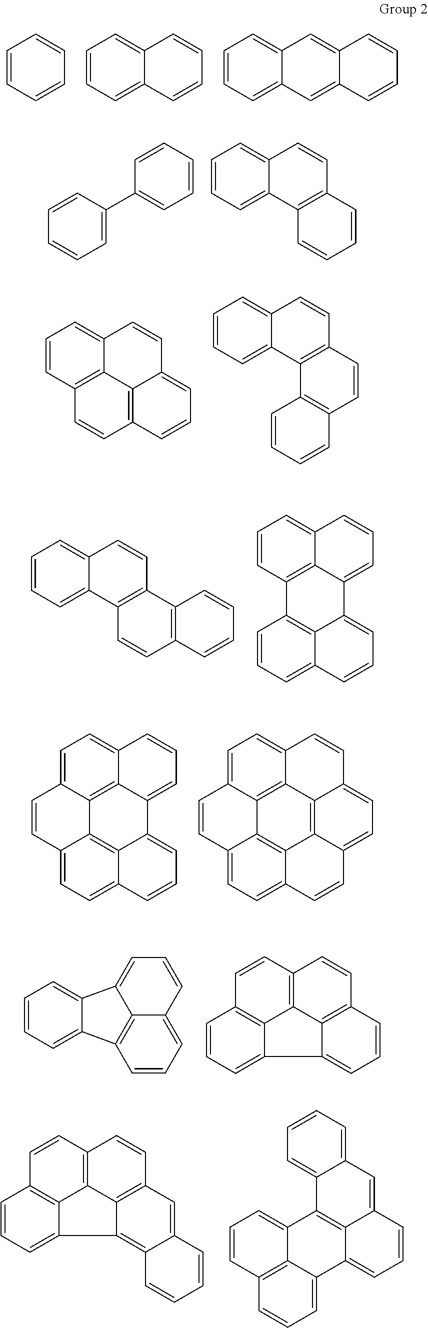

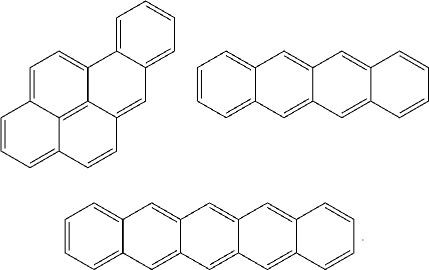

The resin may have a weight average molecular weight of about 500 to about 20,000.

The resin may be included in an amount of about 0.1 wt % to about 50 wt % based on a total amount (100 wt %) of the semiconductor photoresist composition.

If (e.g., when) the resin is included in the above content (e.g., amount) range, it may have excellent or suitable etch resistance and heat resistance.

The semiconductor photoresist composition according to one or more embodiments may include (e.g., consist of) the aforementioned organometallic compound, solvent, and resin. However, in some embodiments, the semiconductor photoresist composition according to the present embodiments may further include additives. Examples of the additives may be a surfactant, a crosslinking agent, a leveling agent, an organic acid, a quencher, and/or a (e.g., any suitable) combination thereof.

The surfactant may include for example an alkyl benzene sulfonate salt, an alkyl pyridinium salt, polyethylene glycol, a quaternary ammonium salt, and/or a (e.g., any suitable) combination thereof, but the present disclosure is not limited thereto.

The crosslinking agent may be for example a melamine-based crosslinking agent, a substituted urea-based crosslinking agent, an acryl-based crosslinking agent, an epoxy-based crosslinking agent, and/or a polymer-based crosslinking agent, but the present disclosure is not limited thereto. The crosslinking agent may have at least two crosslinking forming substituents, for example, a compound such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, methoxymethylated thiourea, and/or the like.

The leveling agent may be utilized for improving coating flatness during printing and may be any suitable leveling agent (e.g., a commercially available leveling agent).

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, and/or a (e.g., any suitable) combination thereof, but the present disclosure is not limited thereto.

The quencher may be diphenyl (p-tolyl) amine, methyl diphenyl amine, triphenyl amine, phenylenediamine, naphthylamine, diaminonaphthalene, and/or a (e.g., any suitable) combination thereof.

Amounts of the corresponding additives may be controlled or selected depending on desired or suitable properties.

In one or more embodiments, the semiconductor photoresist composition may further include a silane coupling agent as an adherence enhancer in order to improve a close-contacting force with the substrate (e.g., in order to improve adherence of the semiconductor photoresist composition to the substrate). The silane coupling agent may be, for example, a silane compound including a carbon-carbon unsaturated bond (such as vinyltrimethoxysilane, vinyl triethoxysilane, vinyl trichlorosilane, and/or vinyl tris(β-methoxyethoxy)silane); 3-methacryloxypropyltrimethoxysilane; 3-acryloxypropyltrimethoxysilane; p-styryl trimethoxysilane; 3-methacryloxypropylmethyldimethoxysilane; 3-methacryloxypropylmethyl diethoxysilane; trimethoxy[3-(phenylamino)propyl]silane and/or the like, but the present disclosure is not limited thereto.

The semiconductor photoresist composition may be formed into a pattern having a relatively high aspect ratio without a collapse. Accordingly, in order to form (or provide) a fine pattern having a width of, for example, about 5 nanometer (nm) to about 100 nm, for example, about 5 nm to about 80 nm, for example, about 5 nm to about 70 nm, for example, about 5 nm to about 50 nm, for example, about 5 nm to about 40 nm, for example, about 5 nm to about 30 nm, or for example, about 5 nm to about 20 nm, the semiconductor photoresist composition may be utilized for a photoresist process utilizing light having a wavelength in a range of about 5 nm to about 150 nm, for example, about 5 nm to about 100 nm, about 5 nm to about 80 nm, about 5 nm to about 50 nm, about 5 nm to about 30 nm, or about 5 nm to about 20 nm. Accordingly, the semiconductor photoresist composition according to one or more embodiments may be utilized to realize extreme ultraviolet lithography utilizing an EUV light source of a wavelength of about 13.5 nm.

According to one or more embodiments, a method of forming (or providing) patterns utilizing the semiconductor photoresist composition according to the present embodiments is provided. For example, the manufactured pattern may be a photoresist pattern.

The method of forming (or providing) patterns according to one or more embodiments includes forming (or providing) an etching-objective layer on a substrate, coating the semiconductor photoresist composition on the etching-objective layer to form (or provide) a photoresist layer, patterning the photoresist layer to form (or provide) a photoresist pattern, and etching the etching-objective layer utilizing the photoresist pattern as an etching mask.

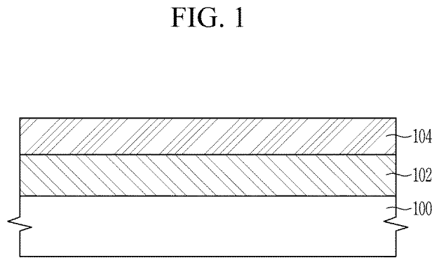

Hereinafter, a method of forming (or providing) patterns utilizing the semiconductor photoresist composition is described referring to FIGS. 1 to 5. FIGS. 1 to 5 are cross-sectional views for explaining a method of forming (or providing) patterns utilizing a semiconductor photoresist composition according to one or more embodiments.

Referring to FIG. 1, an object to be etched is prepared. The aspect to be etched may be a thin film 102 formed on a semiconductor substrate 100. Hereinafter, the object to be etched is limited to the thin film 102. A whole (e.g., an entire or substantially entire) surface of the thin film 102 is washed to remove impurities and/or the like remaining thereon. The thin film 102 may be for example a silicon nitride layer, a polysilicon layer, and/or a silicon oxide layer.

Subsequently, the resist underlayer composition for forming (or providing) a resist underlayer 104 is spin-coated on the surface of the washed thin film 102. However, one or more embodiments is not limited thereto, and one or more suitable coating methods, for example a spray coating, a dip coating, a knife edge coating, a printing method, for example, an inkjet printing and/or a screen printing, and/or the like may be utilized.

Hereinafter, a process including a coating of the resist underlayer is described. However, in some embodiments, the coating process of the resist underlayer may not be provided (e.g., may be omitted).

Then, the coated composition is dried and baked to form (or provide) a resist underlayer 104 on the thin film 102. The baking may be performed at about 100° C. to about 500° C., for example, about 100° C. to about 300° C.

The resist underlayer 104 is formed between the substrate 100 and a photoresist layer 106 and thus may prevent or reduce non-uniformity in pattern-forming (or providing) capability and of a photoresist line width if (e.g., when) a ray reflected from on the interface between the substrate 100 and the photoresist layer 106, and/or a hardmask between layers, is scattered into an unintended (or undesirable) photoresist region.

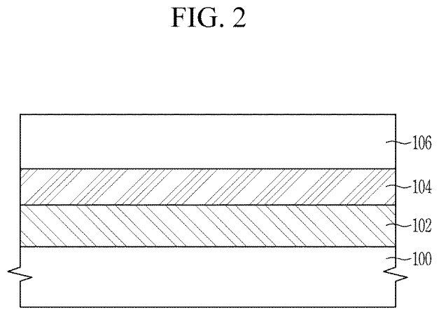

Referring to FIG. 2, the photoresist layer 106 is formed by coating the semiconductor photoresist composition on the resist underlayer 104. The photoresist layer 106 may be obtained by coating the semiconductor photoresist composition on the thin film 102 formed on the substrate 100 and then, curing it through a heat treatment.

For example, the formation of a pattern by utilizing the semiconductor photoresist composition may include coating the semiconductor photoresist composition on the substrate 100 having the thin film 102 coated thereon. The semiconductor photoresist composition may be coated through spin coating, slit coating, inkjet printing, and/or the like and then, dried to form the photoresist layer 106.

The semiconductor photoresist composition has already been illustrated herein and will not be illustrated again.

Subsequently, a substrate 100 having the photoresist layer 106 is subjected to a first baking process. The first baking process may be performed at about 80° C. to about 120° C.

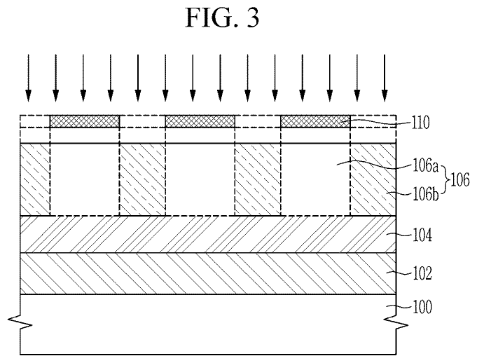

Referring to FIG. 3, the photoresist layer 106 may be selectively exposed utilizing a patterned mask 110.

For example, the exposure may utilize an activation radiation with light having a relatively high energy wavelength such as EUV (extreme ultraviolet; a wavelength of about 13.5 nm), an E-Beam (an electron beam), and/or the like, as well as such as an i-line (a wavelength of about 365 nm), a KrF excimer laser (a wavelength of about 248 nm), an ArF excimer laser (a wavelength of about 193 nm), and/or the like.

For example, light for the exposure according to one or more embodiments may have a wavelength in a range of about 5 nm to about 150 nm and a relatively high energy wavelength, for example, EUV (extreme ultraviolet; a wavelength of 13.5 nm), an E-Beam (an electron beam), and/or the like.

The exposed region 106b of the photoresist layer 106 has a different solubility from the unexposed region 106a of the photoresist layer 106, where the exposed region 106b forms a polymer by a crosslinking reaction such as condensation between organometallic compounds.

Subsequently, the substrate 100 is subjected to a second baking process. The second baking process may be performed at a temperature of about 90° C. to about 200° C. The exposed region 106b of the photoresist layer 106 becomes substantially indissoluble by a developer (e.g., a developing composition) due to the second baking process.

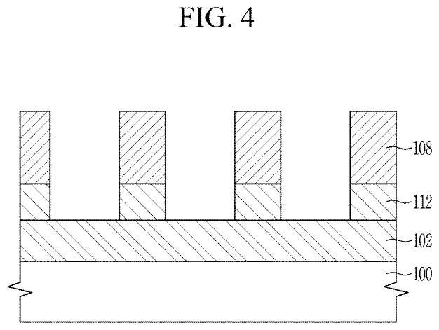

In FIG. 4, the unexposed region 106a of the photoresist layer is dissolved and removed utilizing the developer to form (or provide) a photoresist pattern 108. For example, the unexposed region 106a of the photoresist layer is dissolved and removed by utilizing an organic solvent such as 2-heptanone and/or the like to complete the photoresist pattern 108 corresponding to the negative tone image.

As described above, a developer (e.g., a developing composition) utilized in a method of forming (or providing) patterns according to one or more embodiments may be an organic solvent. The organic solvent utilized in the method of forming (or providing) patterns according to one or more embodiments may be, for example, selected from among ketones (such as methylethylketone, acetone, cyclohexanone, 2-heptanone, and/or the like), alcohols (such as 4-methyl-2-propanol, 1-butanol, isopropanol, 1-propanol, methanol, and/or the like), esters (such as propylene glycol monomethyl ether acetate, ethyl acetate, ethyl lactate, n-butyl acetate, butyrolactone, and/or the like), aromatic compounds (such as benzene, xylene, toluene, and/or the like), and/or a (e.g., any suitable) combination thereof.

However, the photoresist pattern according to one or more embodiments is not necessarily limited to the negative tone image but may be formed to have a positive tone image. Herein, a developer utilized for forming (or providing) the positive tone image may be a quaternary ammonium hydroxide composition such as tetraethylammonium hydroxide, tetrapropylammonium hydroxide, tetrabutylammonium hydroxide, and/or a (e.g., any suitable) combination thereof.

As described above, exposure to light having a relatively high energy such as EUV (extreme ultraviolet; a wavelength of 13.5 nm), an E-Beam (an electron beam), and/or the like, as well as light having a wavelength such as i-line (wavelength of about 365 nm), KrF excimer laser (wavelength of about 248 nm), ArF excimer laser (wavelength of about 193 nm), and/or the like, may provide a photoresist pattern 108 having a width of a thickness (e.g., a width) of about 5 nm to about 100 nm. For example, the photoresist pattern 108 may have a width of a thickness of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In some embodiments, the photoresist pattern 108 may have a half-pitch of less than or equal to about 50 nm, for example less than or equal to about 40 nm, for example less than or equal to about 30 nm, for example less than or equal to about 20 nm, for example less than or equal to about 15 nm, and a line width roughness of less than or equal to about 10 nm, less than or equal to about 5 nm, less than or equal to about 3 nm, or less than or equal to about 2 nm.

Subsequently, the photoresist pattern 108 is utilized as an etching mask to etch the resist underlayer 104. Through this etching process, an organic layer pattern 112 is formed. The organic layer pattern 112 also may have a width corresponding to that of the photoresist pattern 108.

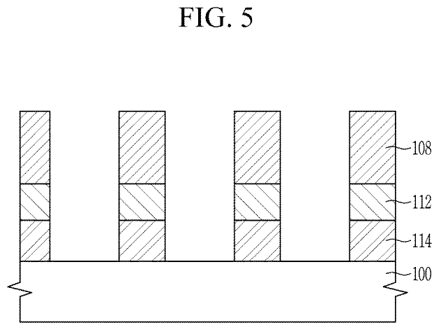

Referring to FIG. 5, the exposed thin film 102 is etched by applying the photoresist pattern 108 as an etching mask. As a result, the thin film is formed as a thin film pattern 114.

The etching of the thin film 102 may be for example dry etching utilizing an etching gas, and the etching gas may be for example CHF₃, CF₄, Cl₂, BCl₃, and/or a mixed gas thereof.

In the exposure process, the thin film pattern 114 formed by utilizing the photoresist pattern 108 formed through the exposure process performed with an EUV light source may have a width corresponding to that of the photoresist pattern 108. For example, the thin film pattern 114 may have a width of 5 nm to 100 nm which is equal to that of the photoresist pattern 108. For example, the thin film pattern 114 formed by utilizing the photoresist pattern 108 formed through the exposure process performed by utilizing an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, and more specifically a width of less than or equal to about 20 nm, like that of the photoresist pattern 108.

Hereinafter, the present disclosure will be described in more detail through examples of the preparation of the semiconductor photoresist composition according to the present embodiments. However, the present disclosure is technically not restricted by the following examples.

### Synthesis of Organic Tin Compound

### Synthesis Example 1: Synthesis of Compounds Represented by Chemical Formula 2

10 g of tin t-butyl trisisopropoxide was added to a 100 mL Schlenk flask, 31 mL of anhydrous dichloromethane was added, and stirred at 0° C. in a nitrogen atmosphere.

6.3 g of acetylacetone was slowly added at 0° C. A solution was stirred at room temperature for 3 hours. The solution temperature was lowered to 0° C., 1.89 g of acetic acid was slowly added, and stirred at room temperature for 12 hours.

Normal hexane was added to the reaction solution and stored at low temperature to produce a solid.

The solid was filtered under a nitrogen atmosphere and washed with normal hexane to obtain a compound as a white solid represented by Chemical Formula 2.

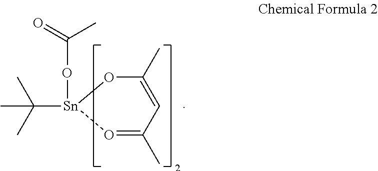

### Synthesis Example 2: Synthesis of Compounds Represented by Chemical Formula 3

10 g of tin t-butyl trisisopropoxide was added to a 100 mL Schlenk flask, 31 mL of anhydrous dichloromethane was added, and stirred at 0° C. in a nitrogen atmosphere.

A solution of 3.15 g of acetylacetone and 3.78 g of acetic acid was slowly added at 0° C. and stirred at room temperature for 12 hours.

The reaction solution was concentrated under reduced pressure to remove dichloromethane to obtain a compound represented by Chemical Formula 3.

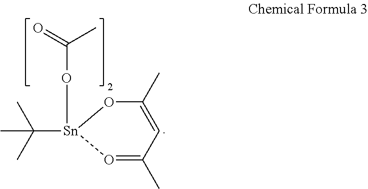

### Synthesis Example 3: Synthesis of Compounds Represented by Chemical Formula 4

10 g of tin t-butyl trisisopropoxide was added to a 100 mL Schlenk flask, 31 mL of anhydrous dichloromethane was added, and stirred at 0° C. in a nitrogen atmosphere.

6.3 g of acetylacetone was slowly added at 0° C. A solution was stirred at room temperature for 3 hours.

Normal hexane was added to the reaction solution and stored at low temperature to produce a solid.

The solid was filtered under a nitrogen atmosphere and washed with normal hexane to obtain a compound as a white solid represented by Chemical Formula 4.

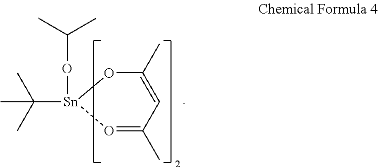

### Synthesis Example 4: Synthesis of Compounds Represented by Chemical Formula 5

10 g of tin t-butyl trisisopropoxide was added to a 100 mL Schlenk flask, 31 mL of anhydrous dichloromethane was added, and stirred at 0° C. in a nitrogen atmosphere.

3.15 g of acetylacetone was slowly added at 0° C. and stir at room temperature for 3 hours.

The reaction solution was concentrated under reduced pressure to remove dichloromethane to obtain a compound represented by Chemical Formula 5.

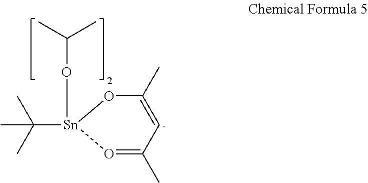

### Comparative Synthesis Example 1

8.5 g of nBuSnCl₃ (butyltin trichloride) was dissolved in anhydrous pentane and the temperature was lowered to 0° C. Afterwards, 10.0 g of trimethylamine was slowly added dropwise, then 4.2 g of ethanol was added and stirred at room temperature for 5 hours. When the reaction was completed, it was filtered, concentrated, and vacuum dried to obtain a compound represented by Chemical Formula 6.

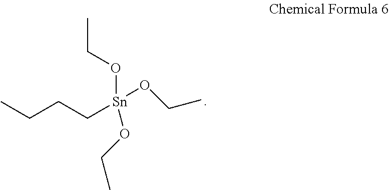

### Comparative Synthesis Example 2

A compound represented by Chemical Formula 7 was obtained by synthesizing in substantially the same manner as Comparative Synthesis Example 1, except that BnSnCl₃ (benzyltin trichloride) was utilized instead of nBuSnCl₃ utilized in Comparative Synthesis Example 1.

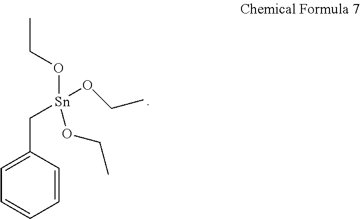 [SMILES: CC[O][Sn]([CH2]c1ccccc1)([O]CC)[O]CC]

### Preparation of Semiconductor Photoresist Compositions

### Examples 1 to 4 and Comparative Examples 1 and 2

The compounds represented by Chemical Formula 2 to Chemical Formula 5 obtained in Synthesis Examples 1 to 4 and the compounds represented by Chemical Formula 6 and Chemical Formula 7 obtained in Comparative Synthesis Examples 1 and 2 were respectively dissolved in 4-methyl-2-pentanol, and filtered through a 0.1 μm PTFE syringe filter to prepare photoresist compositions.

A 4-inch diameter circular silicon wafer with a native-oxide surface was utilized as a substrate for thin film deposition. Before deposition of the resist thin film, the wafer was treated in a UV ozone cleaning system for 10 minutes, the resist composition was spin-coated on the wafer at 1500 rpm for 30 seconds, and baked at 120° C. for 120 seconds to form (or provide) a thin film. Then, the thickness of the film after coating and firing was measured through ellipsometry and was found to be about 25 nm for Examples 1 to 4, and about 20 nm for Comparative Examples 1 and 2.

### Evaluation 1: Sensitivity Evaluation

The substrate, on which the resist thin film was deposited, was exposed to an E-beam with an acceleration voltage of 100 Kv to form (or provide) nanowires of 40 nm half-pitch. The irradiated substrate was exposed to 40° C. for 30 seconds, then dipped into a petri dish containing 2-heptanone for 60 seconds, taken out, washed with the same solvent for about 10 seconds, and finally baked at 150° C. To confirm a pattern performance of a patterning substrate, the CD (critical dimension) size of the formed line was measured utilizing FE-SEM (field emission scanning electron microscopy) images. Sensitivity was indicated as ⊚ if the CD size is more than or equal to 40 nm, ∘ if it is more than or equal to 35 nm, and A if it is less than 35 nm at 1000 Uc/cm² energy.

### Evaluation 2: Storage Stability Evaluation

The storage stability of the organometallic compounds utilized in Examples 1 to 4 and Comparative Examples 1 and 2 was evaluated based on the following criteria, and the results were shown in Table 1.

### Storage Stability

When the semiconductor photoresist compositions according to Examples 1 to 4 and Comparative Examples 1 and 2 were left at room temperature (20±5° C.) for a certain period of time, the degree of precipitation was visually observed, and evaluated according to the storage standards.

TABLE 1

| | Organic tin | Storage | |
|---|---|---|---|
| | compound | stability | Sensitivity |
| Example 1 | Chemical | ⊚ | ⊚ |
| | Formula 2 | | |
| Example 2 | Chemical | ○ | ⊚ |
| | Formula 3 | | |
| Example 3 | Chemical | ○ | ○ |
| | Formula 4 | | |
| Example 4 | Chemical | Δ | ○ |
| | Formula 5 | | |
| Comparative | Chemical | X | ○ |
| Example 1 | Formula 6 | | |
| Comparative | Chemical | X | Δ |
| Example 2 | Formula 7 | | |

※ Evaluation criteria
⊚: can be stored for more than or equal to 4 months
○: can be stored for more than or equal to 3 months and less than 4 months
Δ: can be stored for more than or equal to 2 weeks and less than 3 months
X: can be stored for less than 2 weeks

From the results in Table 1, it can be seen that the semiconductor photoresist composition according to the examples has excellent or suitable sensitivity and significantly improved storage stability compared to the comparative examples.

Hereinbefore, the certain embodiments of the present disclosure have been described and illustrated, however, it is apparent to a person with ordinary skill in the art that the present disclosure is not limited to one or more embodiments as described, and may be variously suitably modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure and their equivalents.

### REFERENCE NUMERALS

100: substrate 102: thin film
104: resist underlayer 106: photoresist layer
106a: unexposed region 106b: exposed region
108: photoresist pattern 112: organic layer pattern
110: patterned mask 114: thin film pattern

What is claimed is:

1. A semiconductor photoresist composition, comprising:
an organic tin compound represented by Chemical Formula 1; and
a solvent: 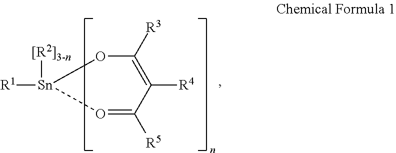
in Chemical Formula 1,
R¹ is
a substituted or unsubstituted C1 to C20 alkyl group,
a substituted or unsubstituted C3 to C20 cycloalkyl group,
a substituted or unsubstituted C2 to C20 alkenyl group,
a substituted or unsubstituted C2 to C20 alkynyl group,
a substituted or unsubstituted C6 to C30 aryl group,
L^{a}-O—R^{a}, wherein L^{a} is a substituted or unsubstituted C1 to C20 alkylene group, and R^{a} is a substituted or unsubstituted C1 to C20 alkyl group or a substituted or unsubstituted C6 to C30 aryl group,
R² is
a halogen, or
—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
—O(CO)R⁶, wherein R⁶ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
—NR⁷R⁸, wherein R⁷ and R⁸ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
—NR⁹(COR¹⁰), wherein R⁹ and R¹⁰ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, or
—NR¹¹C(NR¹²)R¹³, wherein R¹¹, R¹², and R¹³ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, R³ to R⁵ are each independently
hydrogen,
a substituted or unsubstituted C1 to C20 alkyl group,
a substituted or unsubstituted C3 to C20 cycloalkyl group,
a substituted or unsubstituted C2 to C20 alkenyl group,
a substituted or unsubstituted C2 to C20 alkynyl group,
a substituted or unsubstituted C6 to C30 aryl group,
L^{c}-O—R^{c}, wherein L^{c} is a substituted or unsubstituted C1 to C20 alkylene group, and R^{c} is a substituted or unsubstituted C1 to C20 alkyl group or a substituted or unsubstituted C6 to C30 aryl group, and
n is one of integers of 1 to 3.

2. The semiconductor photoresist composition as claimed in claim 1, wherein
n is an integer of 1 or 2.

3. The semiconductor photoresist composition as claimed in claim 1, wherein
R¹ is
a substituted or unsubstituted C1 to C10 alkyl group,
a substituted or unsubstituted C3 to C10 cycloalkyl group,
a substituted or unsubstituted C2 to C10 alkenyl group,
a substituted or unsubstituted C2 to C10 alkynyl group,
a substituted or unsubstituted C6 to C20 aryl group, or
L^{a}-O—R^{a}, wherein L^{a} is a substituted or unsubstituted C1 to C10 alkylene group, and R^{a} is a substituted or unsubstituted C1 to C10 alkyl group.

4. The semiconductor photoresist composition as claimed in claim 3, wherein
R¹ is a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted tert-pentyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, a substituted or unsubstituted methoxy group, a substituted or unsubstituted ethoxy group, a substituted or unsubstituted propoxy group, or a combination thereof, and
R^{a} is a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, or a combination thereof.

5. The semiconductor photoresist composition as claimed in claim 1, wherein
R² is
a halogen,
—OR^{b}, wherein R^{b} is a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a combination thereof,
—O(CO)R⁶, wherein R⁶ is hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a combination thereof,
—NR⁷R⁸, wherein R⁷ and R⁸ are each independently hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a combination thereof,
—NR⁹(COR¹⁰), wherein R⁹ and R¹⁰ are each independently hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a combination thereof, or
—NR¹¹C(NR¹²)R¹³, wherein R¹¹, R¹², and R¹³ are each independently hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a combination thereof.

6. The semiconductor photoresist composition as claimed in claim 5, wherein
R² is
a halogen,
—OR^{b}, wherein R^{b} is a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a combination thereof, or
—O(CO)R⁶, wherein R⁶ is hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a combination thereof.

7. The semiconductor photoresist composition as claimed in claim 5, wherein
R² is —O(CO)R⁶, wherein R⁶ is hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a combination thereof.

8. The semiconductor photoresist composition as claimed in claim 5, wherein
R^{b} is a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, or a combination thereof, and
R⁶ is a hydrogen, a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, or a combination thereof.

9. The semiconductor photoresist composition as claimed in claim 1, wherein
R³ to R⁵ are each independently hydrogen, a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, or a combination thereof.

10. The semiconductor photoresist composition as claimed in claim 1, wherein
the organic tin compound is represented by any one selected from among compounds listed in the Group 1:

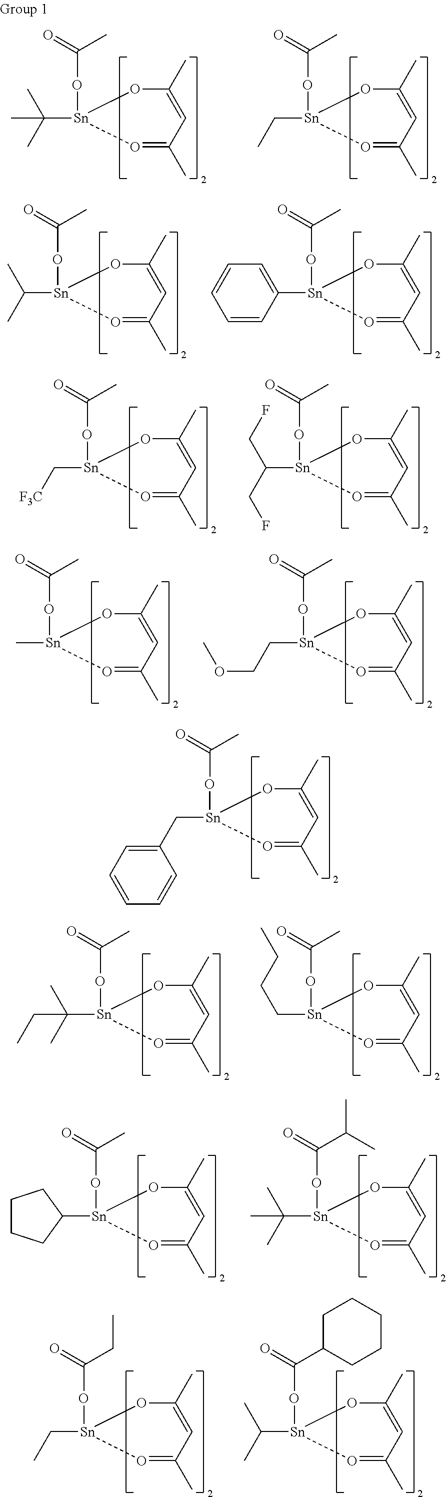

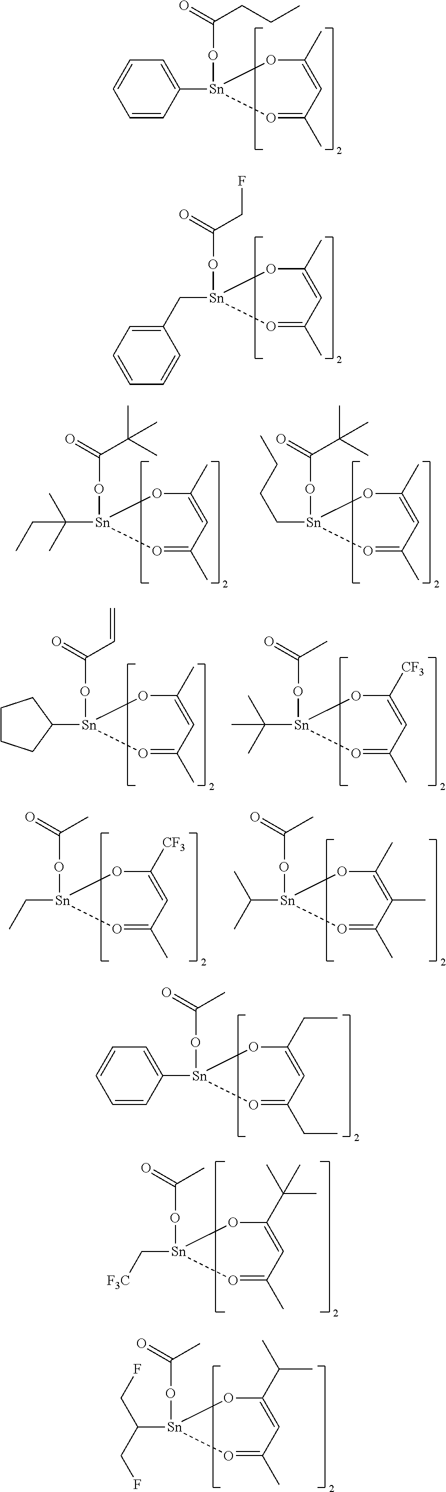

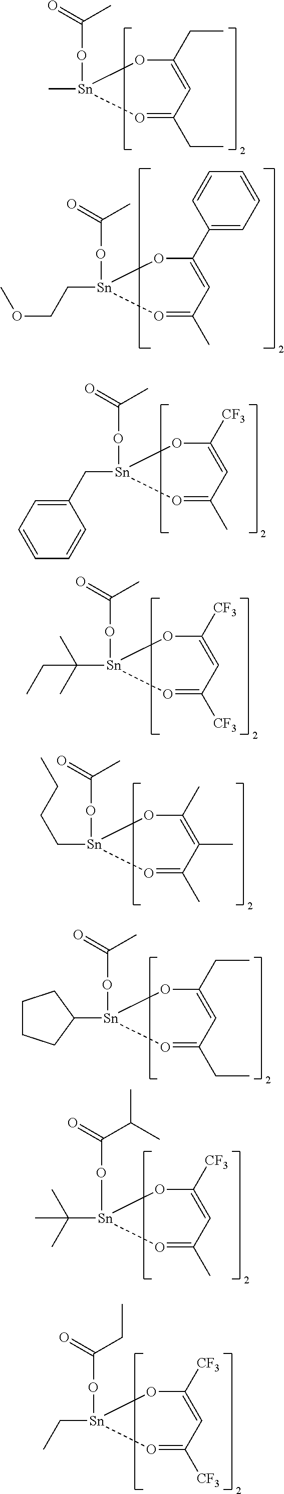

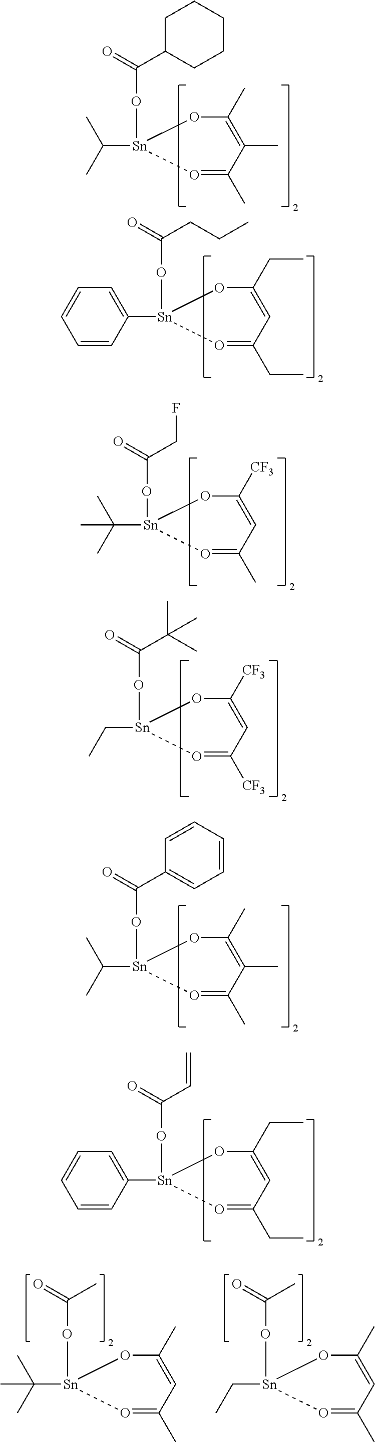

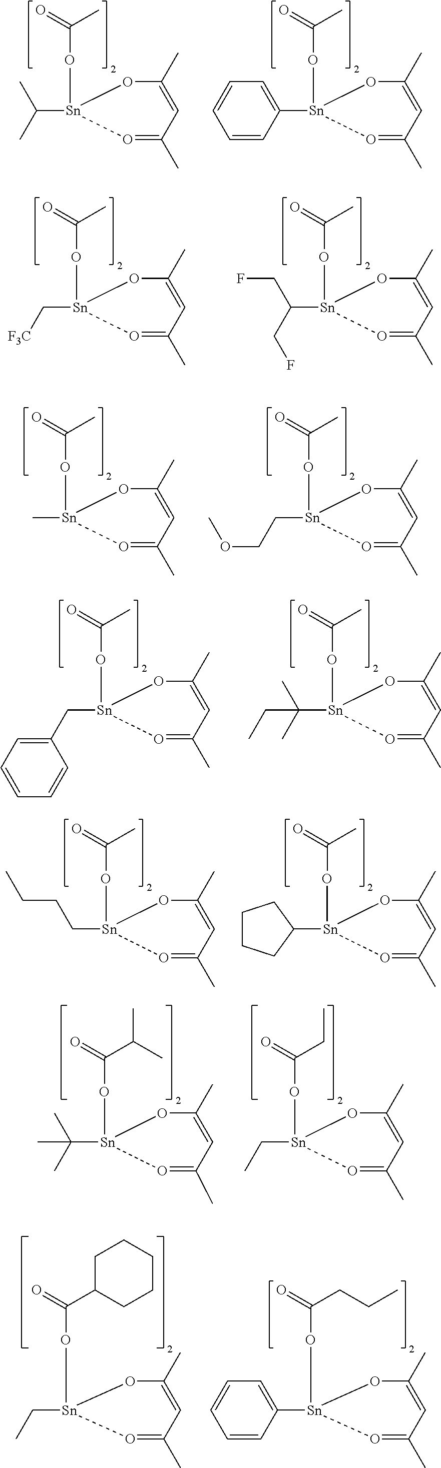

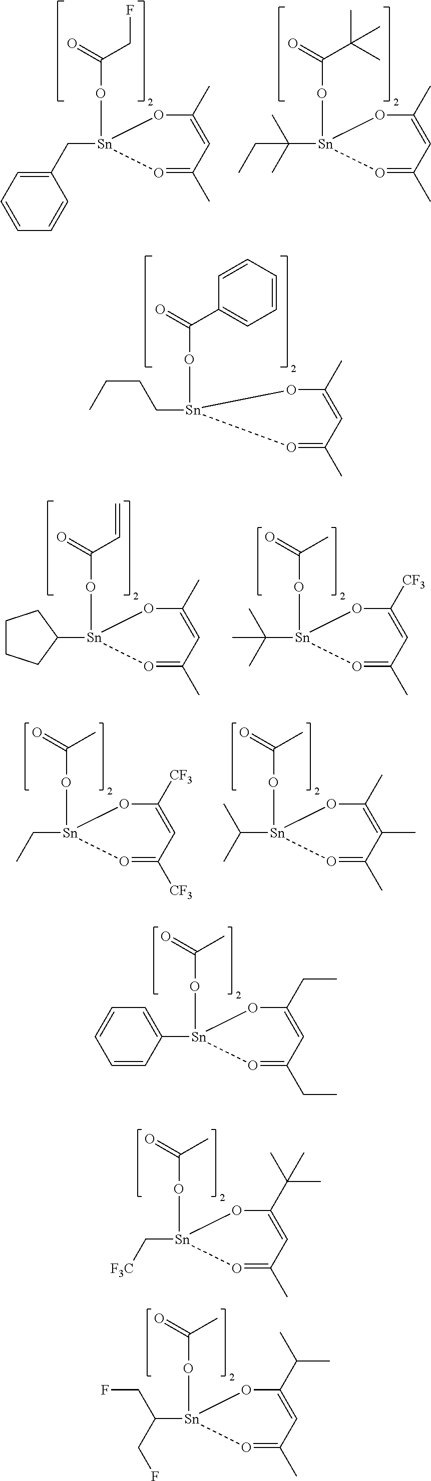

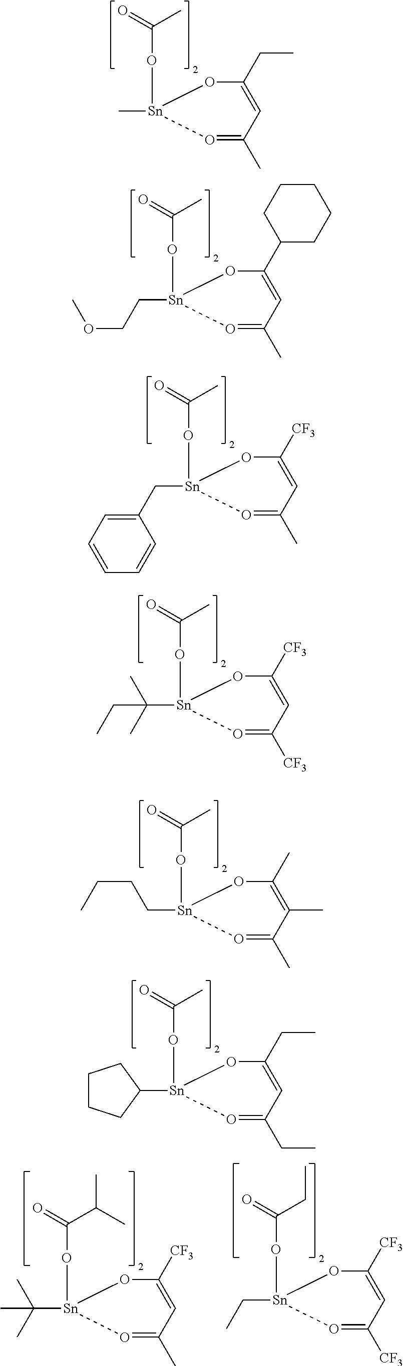

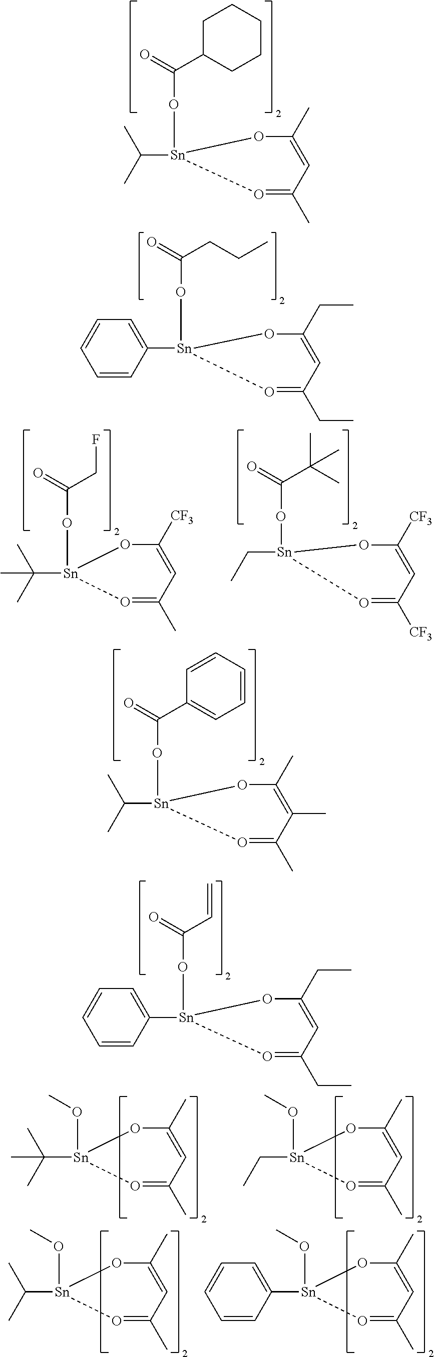

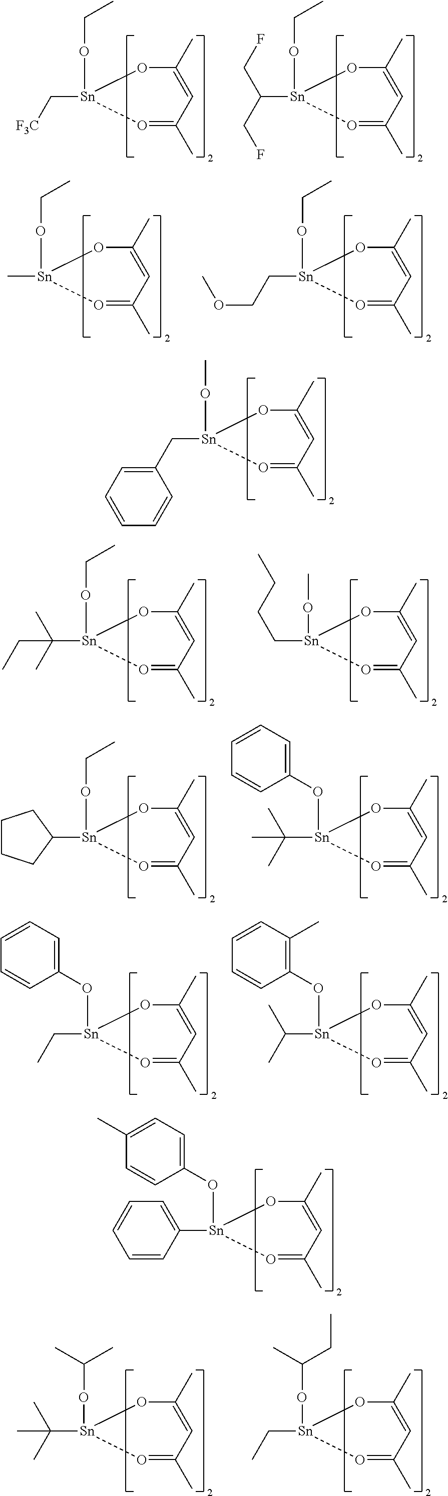

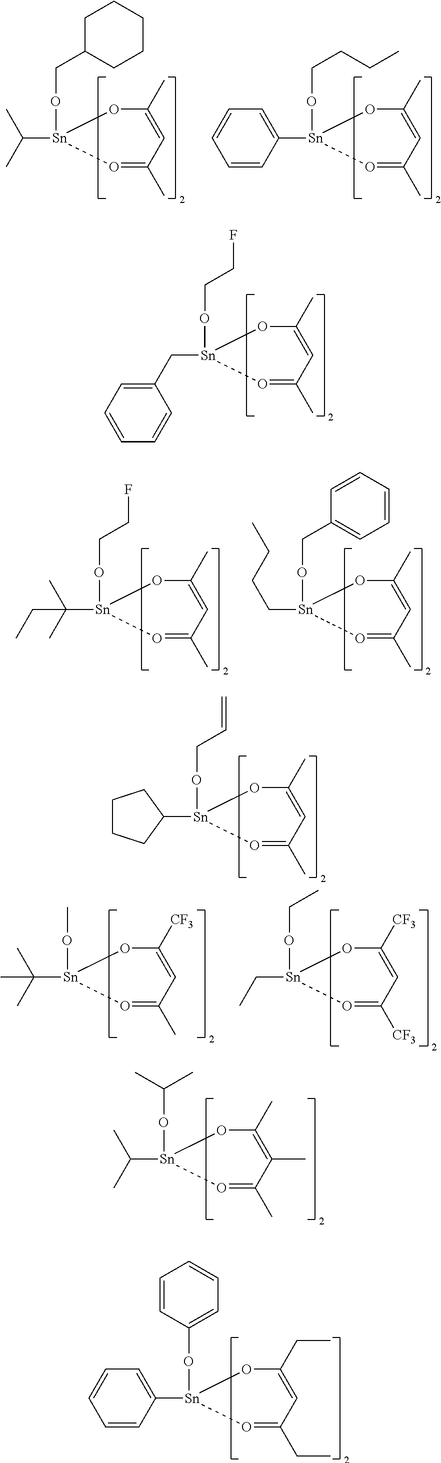

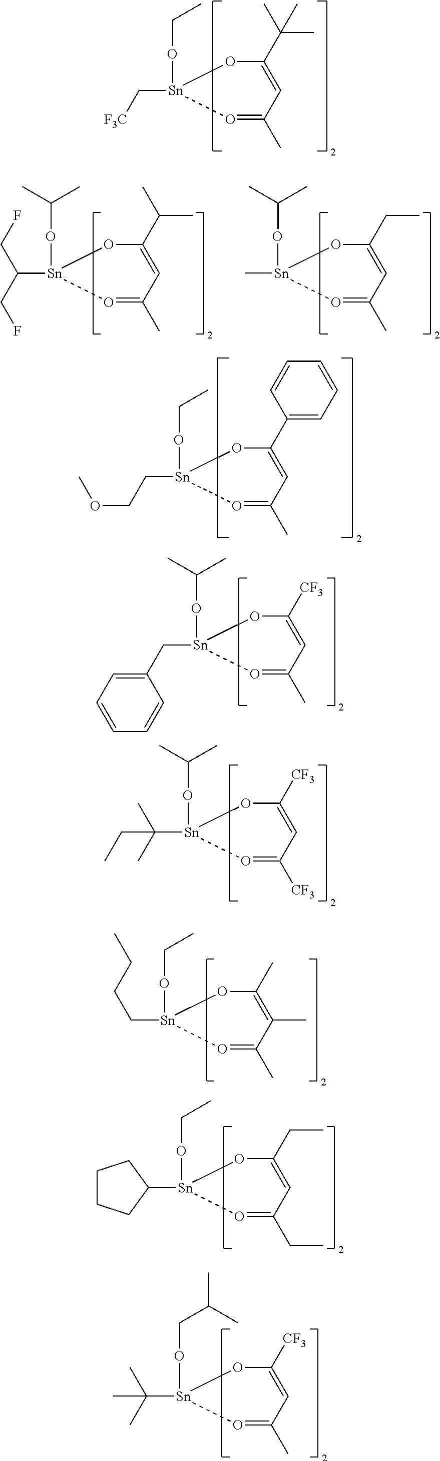

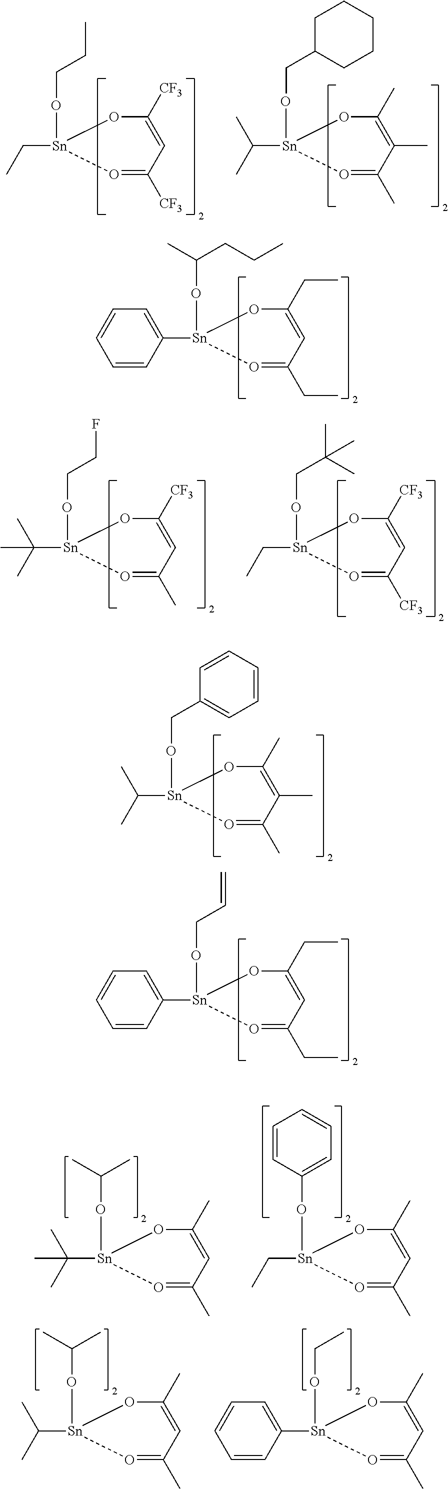

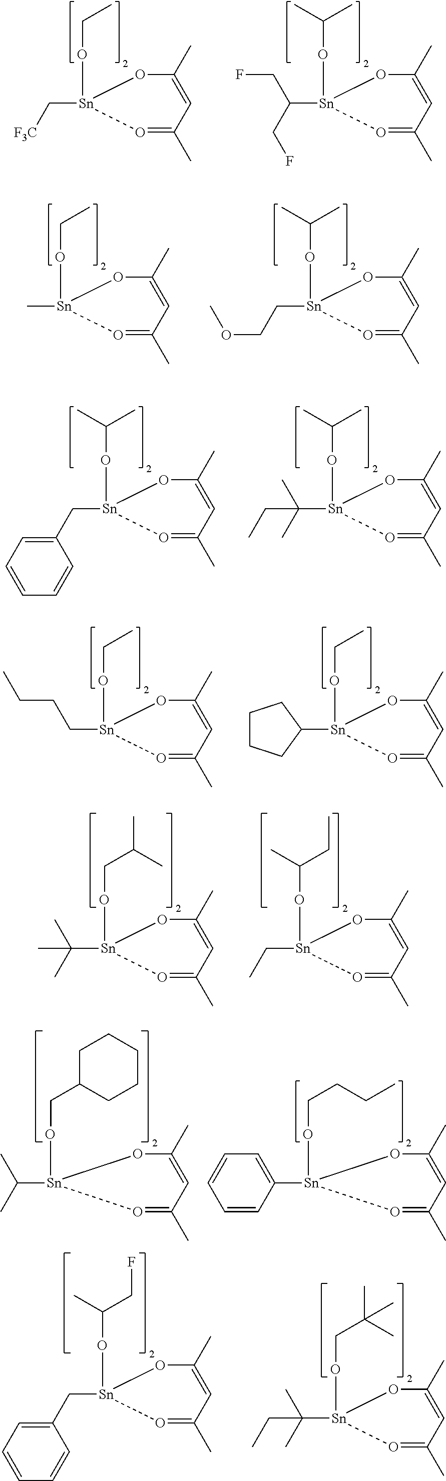

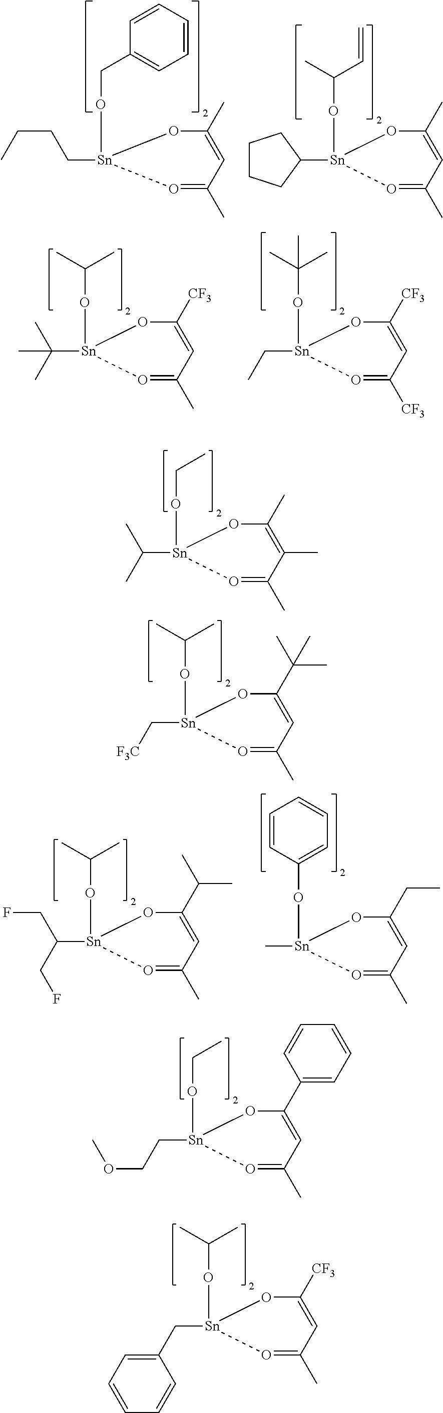

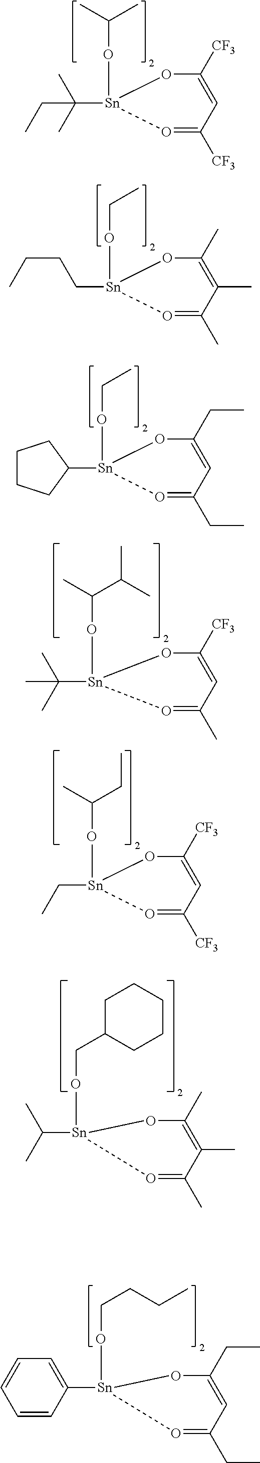

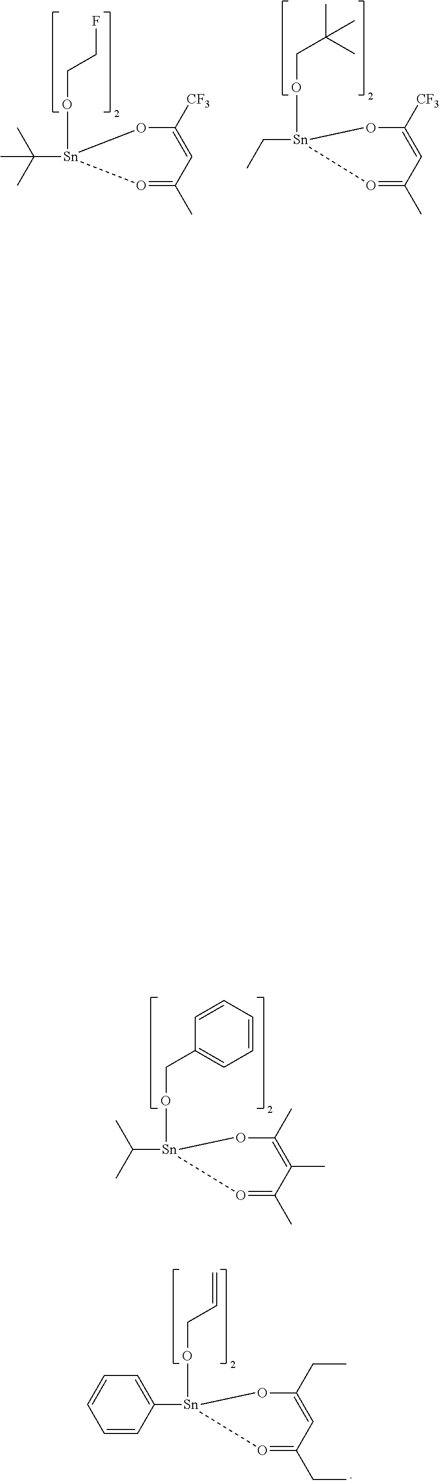

11. The semiconductor photoresist composition as claimed in claim 1, wherein
the organic tin compound is in an amount of about 1 wt % to about 30 wt % based on 100 wt % of the semiconductor photoresist composition.

12. The semiconductor photoresist composition as claimed in claim 1, wherein
the semiconductor photoresist composition further comprises an additive of a surfactant, a cross-linking agent, a leveling agent, or a combination thereof.

13. A method of forming patterns, comprising:
forming an etching-objective layer on a substrate;
coating the semiconductor photoresist composition as claimed in claim 1 on the etching-objective layer to form a photoresist layer;
patterning the photoresist layer to form a photoresist pattern; and
etching the etching-objective layer with the photoresist pattern as an etching mask.

14. The method as claimed in claim 13, wherein the photoresist pattern is formed by applying light in a wavelength of about 5 nanometer (nm) to about 150 nm.

15. The method as claimed in claim 13, wherein
the photoresist pattern has a width of about 5 nanometer (nm) to about 100 nm.
